(19) United States
(12) Patent Application Publication
(10) Pub. No.: US 2025/0110301 A1
(43) Pub. Date: Apr. 3, 2025

(54) TECHNOLOGIES FOR THERMAL PLUGS IN A PHOTONIC INTEGRATED CIRCUIT DIE

(71) Applicant: Intel Corporation, Santa Clara, CA (US)

(72) Inventors: Saeed Fathololoumi, Los Gatos, CA (US); Reece Andrew DeFrees, Rio Rancho, NM (US); Kelly Christopher Magruder, Albuquerque, NM (US); Harel Frish, Albuquerque, NM (US); John M. Heck, Berkeley, CA (US); Ling Liao, Fremont, CA (US); David Chak Wang Hui, Santa Clara, CA (US); Sushrutha Reddy Gujjula, Chandler, AZ (US)

(73) Assignee: Intel Corporation, Santa Clara, CA (US)

(21) Appl. No.: 18/477,836

(22) Filed: Sep. 29, 2023

(51) Int. Cl. G02B 6/42; H01L 23/00; H01L 23/367; H01L 25/16; H01L 25/18

(52) U.S. Cl. CPC G02B 6/4274; G02B 6/4268; H01L 23/3675; H01L 24/05; H01L 24/16; H01L 24/17; H01L 25/165; H01L 25/167; H01L 25/18; H01L 24/32; H01L 24/48; H01L 24/73; H01L 24/81; H01L 2224/05008; H01L 2224/05088; H01L 2224/05093; H01L 2224/05098; H01L 2224/05124; H01L 2224/05144; H01L 2224/05147; H01L 2224/05155; H01L 2224/05171; H01L 2224/05569; H01L 2224/05624; H01L 2224/05644; H01L 2224/05647; H01L 2224/05655; H01L 2224/05671; H01L 2224/16145; H01L 2224/16225; H01L 2224/17181; H01L 2224/32245; H01L 2224/48091; H01L 2224/48225; H01L 2224/73207; H01L 2224/73253; H01L 2224/81815; H01L 2924/01074

(57) ABSTRACT

Technologies for thermal plugs in photonic integrated circuit (PIC) dies are disclosed. In an illustrative embodiment, several thermal plugs extend from contact pads in a PIC die, through a dielectric layer, to a waveguide layer. The thermal plugs can carry heat at a higher rate than the surrounding dielectric layer, increasing the heat transfer through the PIC die. The PIC die may be mounted on an electronic integrated circuit (EIC) die in an integrated circuit component. The PIC die can transfer heat from the EIC die, through the PIC die, and to another component such as an integrated heat spreader, lowering the temperature of the EIC die. The thermal plugs can increase the heat transfer through the PIC die.

### BACKGROUND

Photonic integrated circuits (PICs) can be used for several applications, such as communications. PIC dies may be packaged with other components in a multi-chip package, such as electronic integrated circuit (EIC) dies. In some cases, the PIC die may be positioned between the EIC die and the integrated heat spreader, potentially limiting heat removal from the EIC die.

### BRIEF DESCRIPTION OF THE DRAWINGS

FIG. 1 is an isometric view of an integrated circuit component including a photonic integrated circuit (PIC) die and an electronic integrated circuit (EIC) die.

FIG. 2 is a cross-sectional view of one embodiment of the integrated circuit component of FIG. 1.

FIG. 3 is a cross-sectional view of one embodiment of the PIC die of FIG. 1.

FIG. 4 is a cross-sectional view of one embodiment of the PIC die of FIG. 1.

FIG. 5 is a cross-sectional view of one embodiment of the PIC die of FIG. 1.

FIG. 6 is a bottom-up view of one embodiment of the PIC die of FIG. 1.

FIG. 7 is a simplified flow diagram of at least one embodiment of a method for manufacturing an integrated circuit component including a PIC die and an EIC die.

FIG. 8 is a cross-sectional view of one embodiment of the PIC die at one point in the method of manufacturing of the flow diagram of FIG. 7.

FIG. 9 is a cross-sectional view of one embodiment of the PIC die at one point in the method of manufacturing of the flow diagram of FIG. 7.

FIG. 10 is a cross-sectional view of one embodiment of the PIC die at one point in the method of manufacturing of the flow diagram of FIG. 7.

FIG. 11 is a cross-sectional view of one embodiment of the PIC die at one point in the method of manufacturing of the flow diagram of FIG. 7.

FIG. 12 is a cross-sectional view of one embodiment of the PIC die at one point in the method of manufacturing of the flow diagram of FIG. 7.

FIG. 13 is a cross-sectional view of one embodiment of the PIC die at one point in the method of manufacturing of the flow diagram of FIG. 7.

FIG. 14 is a cross-sectional view of one embodiment of the PIC die at one point in the method of manufacturing of the flow diagram of FIG. 7.

FIG. 15 is a cross-sectional view of one embodiment of the PIC die at one point in the method of manufacturing of the flow diagram of FIG. 7.

FIG. 16 is a cross-sectional view of one embodiment of the PIC die at one point in the method of manufacturing of the flow diagram of FIG. 7.

FIG. 17 is a cross-sectional view of one embodiment of the integrated circuit component of FIG. 1.

FIG. 18 is a top view of a wafer and dies that may be included in a microelectronic assembly, in accordance with any of the embodiments disclosed herein.

FIG. 19 is a cross-sectional side view of an integrated circuit device that may be included in a microelectronic assembly, in accordance with any of the embodiments disclosed herein.

FIGS. 20A-20D are perspective views of example planar, gate-all-around, and stacked gate-all-around transistors.

FIG. 21 is a cross-sectional side view of an integrated circuit device assembly that may include a microelectronic assembly, in accordance with any of the embodiments disclosed herein.

FIG. 22 is a block diagram of an example electrical device that may include a microelectronic assembly, in accordance with any of the embodiments disclosed herein.

### DETAILED DESCRIPTION

In various embodiments disclosed herein, an integrated circuit component includes a photonic integrated circuit (PIC) die and an electronic integrated circuit (EIC) die. In an illustrative embodiment, the PIC die is positioned between the EIC die and an integrated heat spreader. The EIC die is cooled at least partially by heat flowing through the PIC die into the integrated heat spreader. The PIC die includes several thermal plugs that extend through at least one dielectric layer of the PIC die. The thermal plugs have a higher coefficient of thermal conductivity and transport heat through the dielectric layer more efficiently than the dielectric layer itself. In one embodiment, the thermal plugs are positioned below a contact pad and solder ball connected to the EIC die, leading to strong thermal coupling between the EIC die and the thermal plugs.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

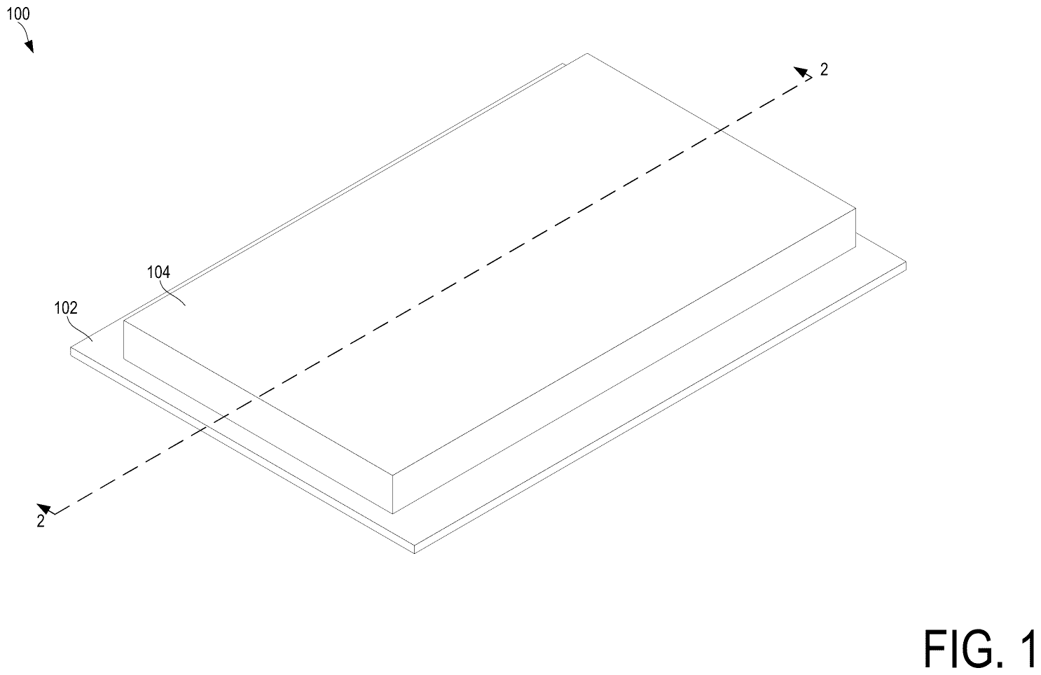

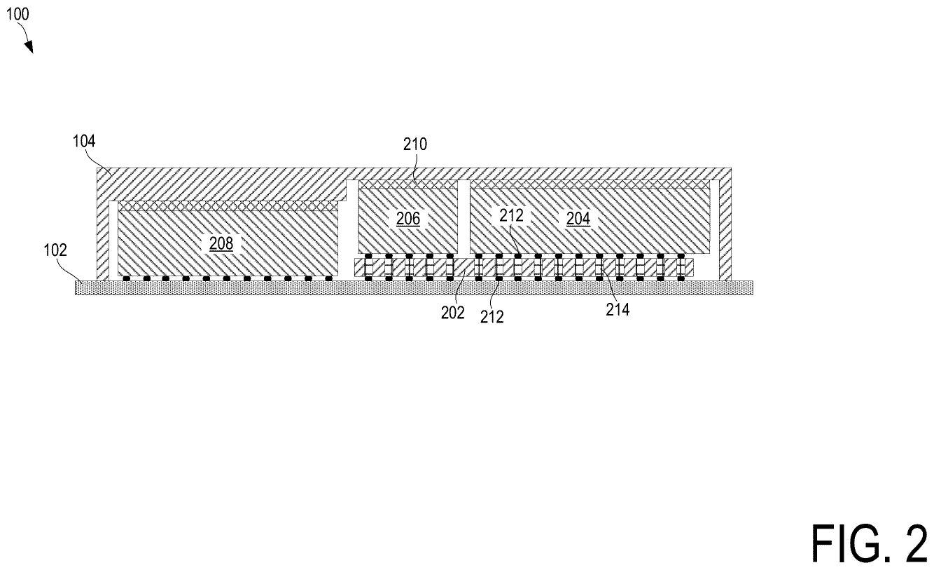

Referring now to FIGS. 1 and 2, in one embodiment, an integrated circuit component 100 includes a circuit board 102, an EIC die 202, a PIC die 204, and an integrated heat spreader 104. FIG. 1 shows a perspective view of the integrated circuit component 100, and FIG. 2 shows a cross-sectional view of one embodiment of the integrated circuit component 100. In an illustrative embodiment, the EIC die 202 is mounted on the circuit board 102, and the PIC die 204 is mounted on the EIC die 202. The integrated circuit component 100 may include other components, such as EIC dies. For example, in one embodiment, the integrated circuit component 100 includes an XPU/I/O hub 208 mounted on the circuit board 102 and a microcontroller 206 mounted on the EIC die 202.

In an illustrative embodiment, the EIC 202 and EIC 208 are connected to the circuit board 102 with solder balls 212, and the EIC 206 and PIC die 204 are connected to the EIC die 202 with solder balls 212. A thermal interface material (TIM) 210 is between the PIC die 204 and EIC dies 206, 208 and the integrated heat spreader 104. The EIC die 206 may include components such as vias 214. Of course, the EIC die 206 may include additional components not explicitly shown in the figures.

The illustrative circuit board 102 may be made from ceramic, glass, and/or organic-based materials with fiberglass and resin, such as FR-4. The circuit board 102 may have any suitable length or width, such as 10-500 millimeters. The circuit board 102 may have any suitable thickness, such as 0.2-5 millimeters. The circuit board 102 may support additional components besides the components shown in FIGS. 1 and 2, such as additional photonic or electronic integrated circuit components, a memory device, additional circuit components, etc.

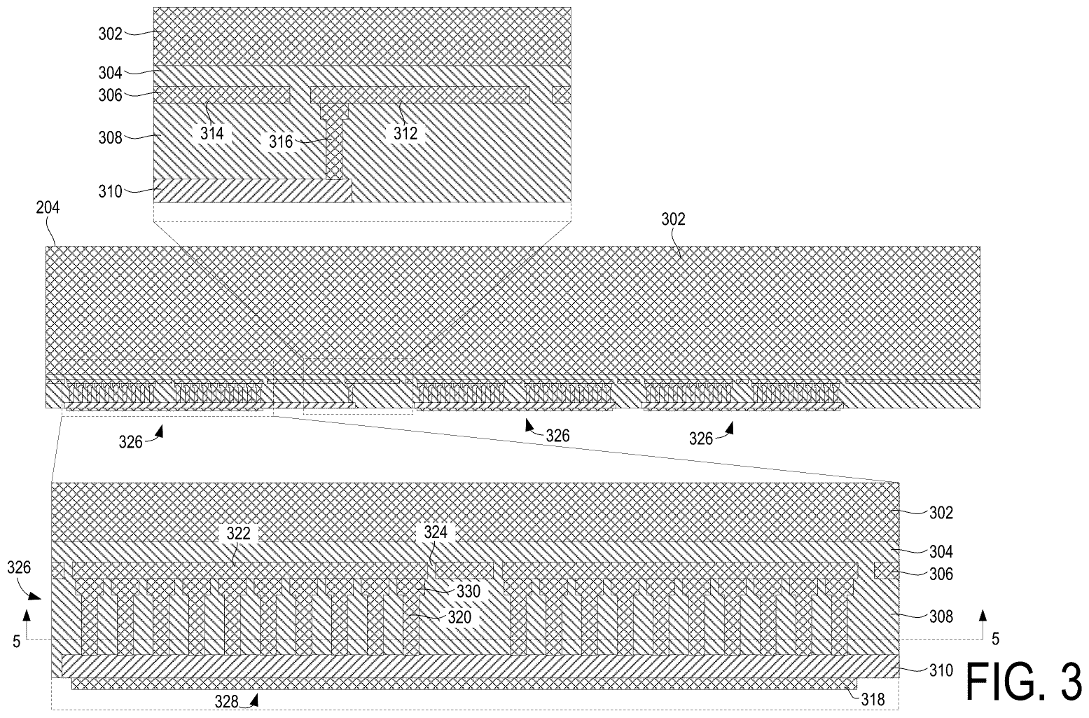

The PIC die 204 may be made of any suitable material, such as silicon. In the illustrative embodiment, waveguides, such as waveguides 312 discussed below in regard to FIG. 3, may be silicon waveguides embedded in silicon oxide cladding. The PIC die 204 may include any suitable number of waveguide inputs and/or outputs, such as 1-1,024. Other optical components, such as optical fibers and/or optical interposers, may be connected to the PIC die 204 to provide optical signals into and out of the waveguides of the PIC die 204. Components such as optical fibers may extend from the integrated circuit component 100, such as through the integrated heat spreader 104 and/or through the circuit board 102 (not shown in FIGS. 1 and 2).

The PIC die 204 is configured to generate, detect, and/or manipulate light. The PIC die 204 may include active or passive optical elements such as splitters, couplers, filters, optical amplifiers, lasers, photodetectors, modulators, etc.

The EIC die 202 may include any suitable electronic integrated circuit component, such as resistors, capacitors, inductors, transistors, etc. The EIC die 202 may include any suitable analog and/or digital circuitry, such as a processor, a memory, an application-specific integrated circuit (ASIC), a field-programmable gate array (FPGA), etc. In some embodiments, the integrated circuit component 100 may be embodied as or otherwise include a router, a switch, a network interface controller, and/or the like. In such embodiments, the EIC die 202 may include network interface controller circuitry to process, parse, route, etc., network packets sent and received by the integrated circuit component 100. Similarly, the EIC dies 206, 208 may be any suitable embodiment of the EIC die 202 described above in combination with any suitable embodiment of the EIC die 202.

The EIC dies 202, 206, 208 and/or the PIC die 204 may have any suitable length or width, such as 1-300 millimeters. The EIC dies 202, 206, 208 and/or the PIC die 204 may have any suitable thickness, such as 0.05-5 millimeters.

The integrated heat spreader 104 may be made of any suitable material with a high thermal conductivity, such as copper, aluminum, other metals, metal alloys, coated metals, combinations of metals, etc. In an illustrative embodiment, the integrated heat spreader 104 is nickel-plated copper. In use, a heat sink with fins or another heat transfer component, such as a liquid-cooled cold plate, may be mated with the integrated heat spreader 104 to remove heat.

The EIC die 202 and/or the PIC die 204 may include any suitable number of solder bumps 212, such as 1-10,000. The solder bumps 212 may be arranged in any suitable pattern, such as a two-dimensional grid. The solder bumps 212 may have any suitable size, such as 10-1,000 micrometers, and any suitable pitch, such as 25 to 1,500 micrometers. The solder bumps 212 may be made of or otherwise include any suitable type of solder, such as tin/lead solder, a lead-free solder, a high-temperature solder, etc. The solder bumps 212 may include by weight, e.g., 0-50% lead, 0-97% tin, 0-50% silver, 0-5% copper, 0-85% gold, or any suitable combination thereof. The melting point of the solder bumps 212 may be, e.g., 180-400° C., depending on the particular application.

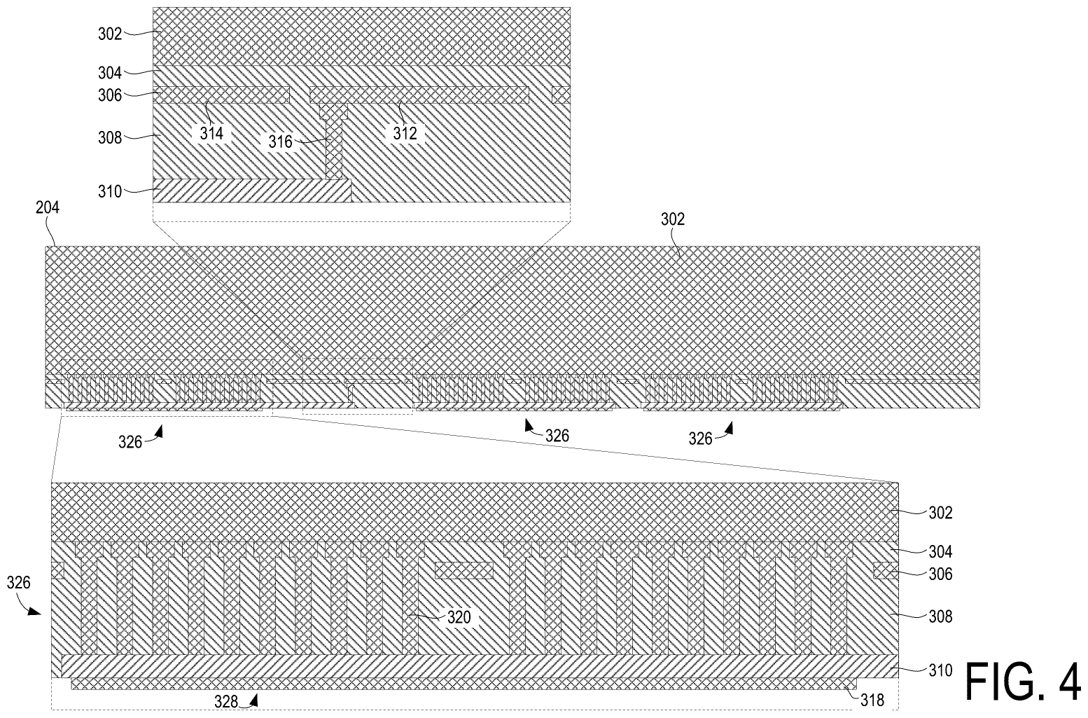

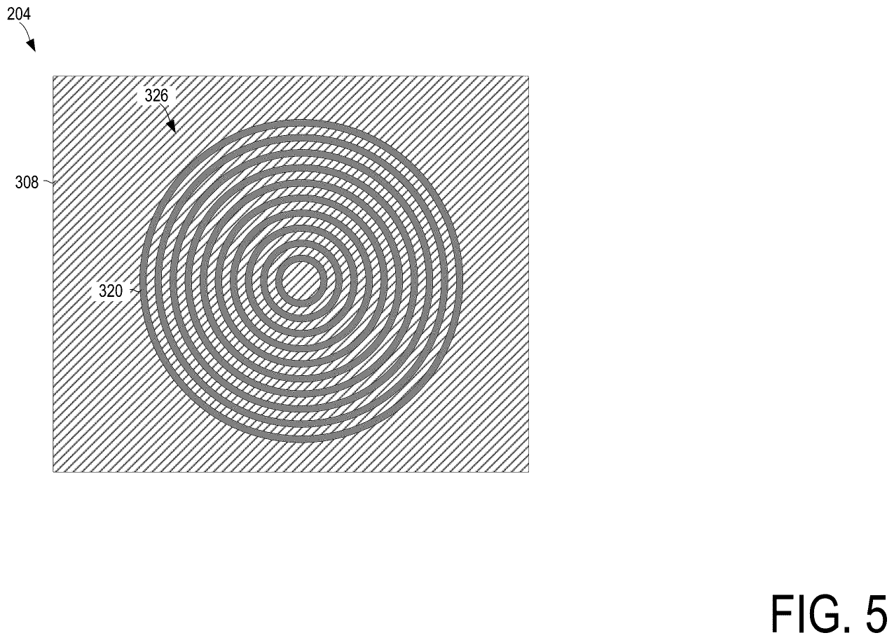

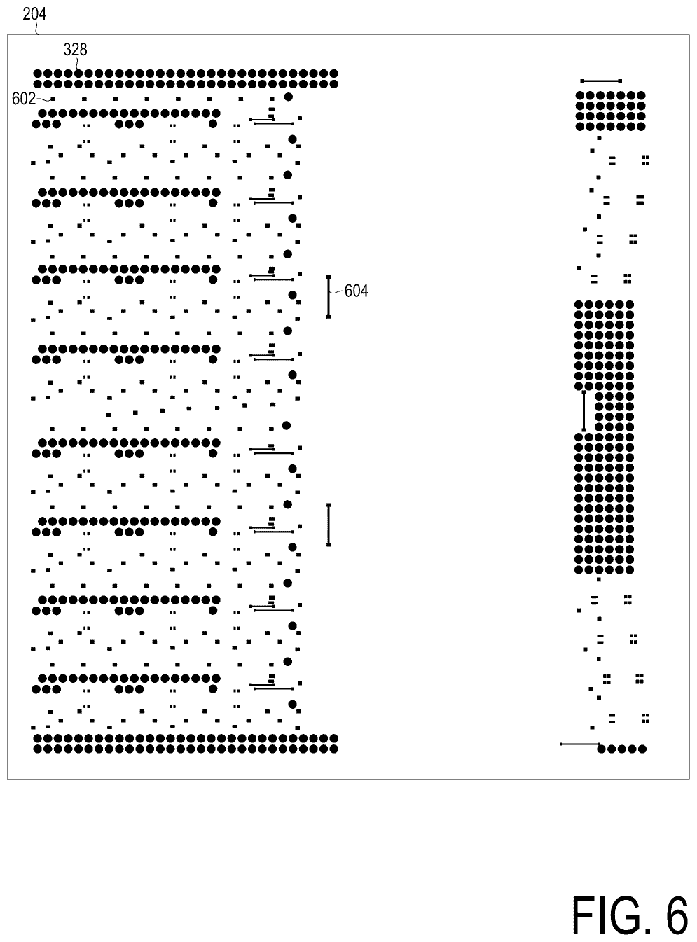

Referring now to FIGS. 3-6, various views of various embodiments of the PIC die 204 are shown. FIG. 3 shows a cross-sectional side view of part of one embodiment of a PIC die 204, FIG. 4 shows a cross-sectional side view of part of one embodiment of a PIC die 204, FIG. 5 shows a cross-sectional top view of part of one embodiment of a PIC die 204, and FIG. 6 shows a top view of one embodiment of a PIC die 204.

In an illustrative embodiment, the PIC die 204 includes a substrate layer 302, a dielectric layer 304 adjacent the substrate layer, a waveguide layer 306 adjacent the dielectric layer 304, and a dielectric layer 308 adjacent the waveguide layer 306. In an illustrative embodiment, the waveguide layer 306 includes a layer of silicon. Parts of the layer of silicon can be etched away using subtractive manufacturing, leaving waveguides 312 defined in the waveguide layer 306 surrounded by dielectric cladding. Unused portions 306 of the waveguide layer 306 may remain in place in positions where they will not interfere with waveguides 312.

The PIC die 204 includes contact pads 328 on a surface of the PIC die 204. The contact pads 328 connect to the solder balls 212 shown in FIG. 2. The illustrative contact pads 328 includes a top pad layer 318 and a trace 310 of a redistribution layer. The trace 310 may connect the contact pad 328 to another component, such as an active component of the PIC die 204. In an illustrative embodiment, a group 326 of thermal plugs 320 are positioned above the contact pad 328. In one embodiment, the thermal plugs 320 are a series of concentric rings. A cross-sectional top view of a group 326 of thermal plugs 320 is shown in FIG. 5, and a cross-sectional side view of a group 326 of thermal plugs 320 is shown in FIG. 3. In one embodiment, the thermal plugs 320 extend to the waveguide layer 306. To electrically isolate the thermal plugs 320 from the rest of the PIC die 202 at the waveguide layer 306, portions of the waveguide layer 306 around the group 326 of thermal plugs 320 is removed and replaced with a dielectric 324, forming an isolated section 322 of the waveguide layer 306. In some embodiments, a segment of the waveguide layer 306 around the group 326 of thermal plugs 320 may be doped to be, e.g., p-n-p junctions or n-p-n junctions, electrically isolating the part of the waveguide layer 306 in contact with the thermal plugs 320. In some embodiments, some or all of the thermal plugs 320 may extend through the waveguide layer 306 and the dielectric layer 304 to the substrate layer 302, as shown in FIG. 5. In such an embodiment, the substrate layer 302 may have a relatively high resistivity in order to electrically isolate the contacts 328 from each other. For example, in one embodiment, the substrate layer 302 may have a resistivity of at least, e.g., 10 Ω·cm. In other embodiments, the substrate layer 302 may have a resistivity of at least, e.g., 1-1,000 Ω·cm.

The contact pads 328 may be connected to various components of the PIC die 204, such as an active component. The contact pads 328 may be connected to the waveguide layer 306 through a trace 310 of a redistribution layer and through a plug 316 extending through the dielectric layer 308 to the waveguide layer 306. The plug 316 may connect to an active component, such as a laser, an amplifier, a detector, a modulator, a switch, etc. The plugs 316, 320 may also be referred to as vias.

FIG. 6 shows a top-down view of one embodiment of a PIC die 204. The PIC die 204 includes arrays of contact pads 328 on the surface. In an illustrative embodiment, groups 326 of thermal plugs 320 may be positioned below any, some, or all of the contact pads. The PIC die 204 may also include additional contacts, pads, traces, components of a redistribution layer, etc., such as traces 602, 604.

In use, in an illustrative embodiment, the contact pads 328 are electrically and thermally coupled to the EIC die 202 through the solder balls 212. The plugs 316 connected to active components of the PIC die 204 are connected to the contact pads 328 and the EIC die 202 through traces 310 in a redistribution layer at or near the surface of the PIC die 204. The group 326 of plugs 320 below the contact pad 328 conduct heat from the EIC die 202 through the dielectric layer 308.

In an illustrative embodiment, the substrate 302 is silicon. In other embodiments, other suitable substrates may be used. The substrate 302 may have any suitable thickness, such as 40-5,000 micrometers.

In an illustrative embodiment, the dielectric layers 304, 308 as well as the dielectric material 324 filling in parts of the waveguide layer 306 is silicon oxide. In other embodiments, other suitable materials may be used for any of the dielectric materials 304, 308, 324, such as silicon nitride, aluminum oxide, hafnium dioxide, polymers, air, etc. In an illustrative embodiment, the dielectric layer 304 is about 2 micrometers thick, and the dielectric layer 308 is about 4 micrometers thick. In other embodiments, the dielectric layers 304, 308 may have any suitable thickness, such as 0.5-20 micrometers.

The waveguide layer 306 may have any suitable thickness, such as 0.2-5 micrometers. The waveguides 312 defined in the silicon waveguide layer 306 may have any suitable width, such as 0.3-3 micrometers. The height of the silicon waveguide layer 306 and the width of the waveguides 312 may be selected to support single-mode operation in the waveguides 312, depending on the wavelength, index of refraction of the waveguides 312, index of refraction of the cladding 304, 324, 308, polarization, etc. The dielectric sections 324 in the waveguide layer 306 may have any suitable width, such as 0.2-5 micrometers. In an illustrative embodiment, the waveguide layer 306 (other than the dielectric material 324) is silicon. In other embodiments, the waveguide layer 306 and/or waveguides 312 in the waveguide layer 306 may be made of or otherwise include silicon nitride, III-V semiconductors, polymers, chalcogenides, lithium niobate, gallium nitride, aluminum oxide, semiconductor dopants, etc. It should be appreciated that metallic traces, such as the plug 316, may extend towards or along some or all of the active waveguides 312, such as for injecting current, receiving current, applying an electric field, sensing an electric field, etc.

In an illustrative embodiment, the plugs 320, 316 are made out of tungsten. In other embodiments, the thermal plugs 320, 316 may be made out of any suitable material with a high thermal conductivity, such as copper, aluminum, silver, nickel, chromium, other metal, etc. The thermal plugs 320, 316 may have any suitable thermal conductivity, such as 80-400 W/(m·K). The traces/pads 310, 318 may be made of any suitable material, such as copper, aluminum, nickel, chromium, gold, etc.

The illustrative plugs 320, 316 may have any suitable dimensions. In an illustrative embodiment, each plug 320 has a ring shape. The height of the ring plugs 320 may be any suitable value, such as the height of the dielectric layer 308 or the height of the dielectric layer 308, waveguide layer 306, and dielectric layer 304. The diameter of the ring plugs 320 and/or a group 326 of ring plugs 320 may be any suitable value, such as 5-50 micrometers. The thickness of the ring plugs 320 (i.e., the difference between inner and outer diameter of the rings) may be any suitable value, such as 1-4 micrometers. The pitch of the ring plugs 320 may be any suitable value, such as 2-6 micrometers. The plugs 316 may have a circular cross-section rather than a ring cross-section with any suitable diameter, such as 1-4 micrometers. In an illustrative embodiment, the base 330 of the plugs 316, 320 may be 0.5-2 micrometers wider than the rest of the plugs 316, 320 and may have any suitable height, such as 0.5-2 micrometers.

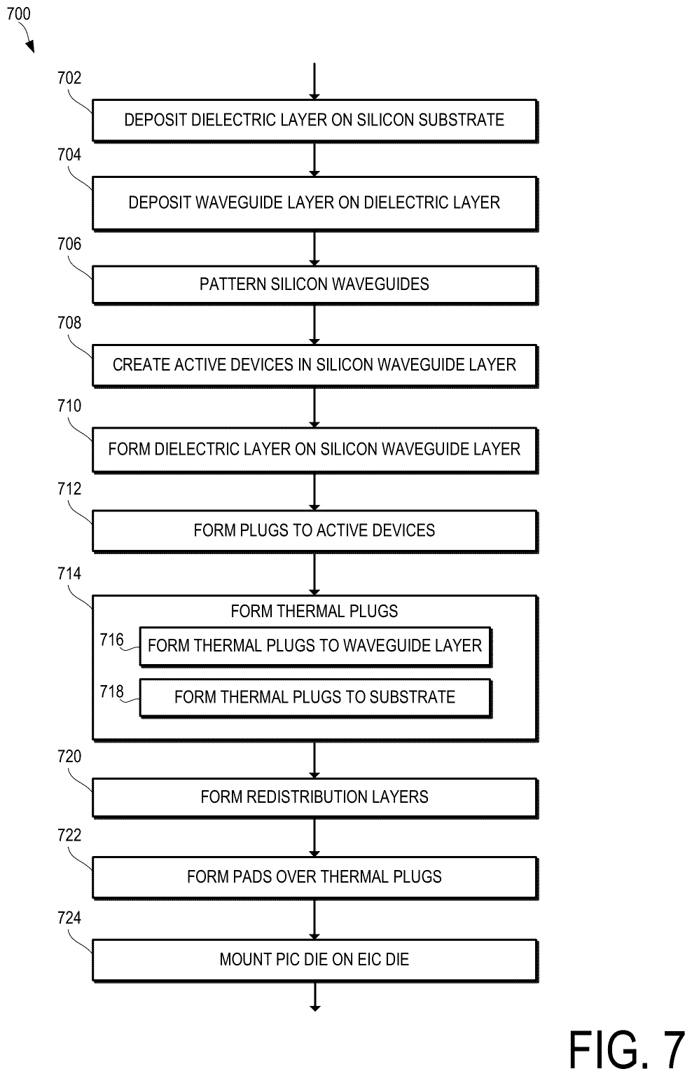

It should be appreciated that the dimensions of the ring plugs 320 and/or plugs 316 described above are merely for one possible embodiment. In particular, the dimensions of the ring plugs 320 and/or plugs 316 may correspond to possible dimensions using an approach of depositing tungsten on sidewalls formed in the dielectric layer 308, described below in more detail in regard to FIGS. 7-16. In other embodiments, the plugs 316, 320 may have different shapes or dimensions. For example, the plugs 316 may be formed in lines, sheets, blocks, etc., of any suitable dimensions, such as 0.5-200 micrometers, subject to certain constraints, such as stress induced on the rest of the PIC die 204.

In use, the groups 326 of thermal plugs 320 may meaningfully reduce the temperature of at least part of the EIC die 202. For example, in one embodiment, a simulation was performed for an EIC die 202 with a maximum temperature specification of 105° C. Without the groups 326 of thermal plugs 320, simulations showed the maximum temperature of the EIC die 202 would reach as high as 108.2° C. in certain regions. With the groups 326 of thermal plugs 320 extending to the waveguide layer 306, as shown in FIG. 3, the maximum temperature of the EIC die 202 would only reach 103.5° C. With the groups 326 of thermal plugs 320 extending to through the dielectric region 304 to the substrate 302, as shown in FIG. 4, the maximum temperature of the EIC die 202 would only reach 102.9° C.

Referring now to FIG. 7, in one embodiment, a flowchart for a method 700 for creating an integrated circuit component 100 is shown. The method 700 may be executed by a technician and/or by one or more automated machines. In some embodiments, one or more machines may be programmed to do some or all of the steps of the method 700. Such a machine may include, e.g., a memory, a processor, data storage, etc. The memory and/or data storage may store instructions that, when executed by the machine, cause the machine to perform some or all of the steps of the method 700. The method 700 may use any suitable set of techniques that are used in semiconductor processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, etc. It should be appreciated that the method 700 is merely one embodiment of a method to create one embodiment of the integrated circuit component 100, and other methods may be used to create any suitable embodiment of the integrated circuit component 100. In some embodiments, steps of the method 700 may be performed in a different order than that shown in the flowchart.

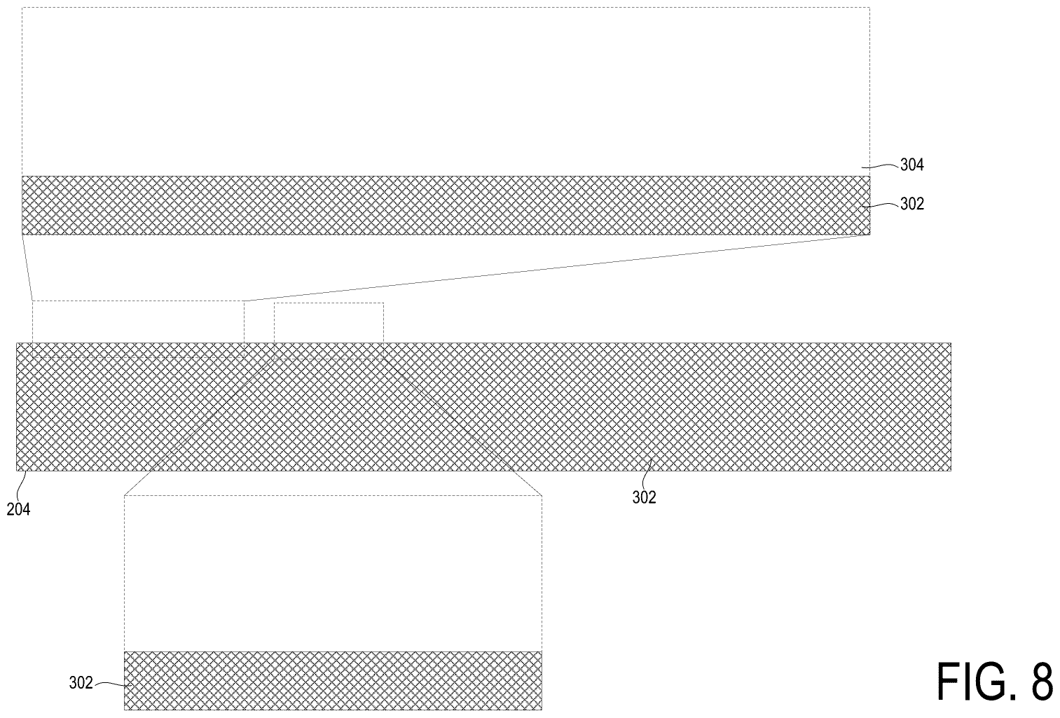

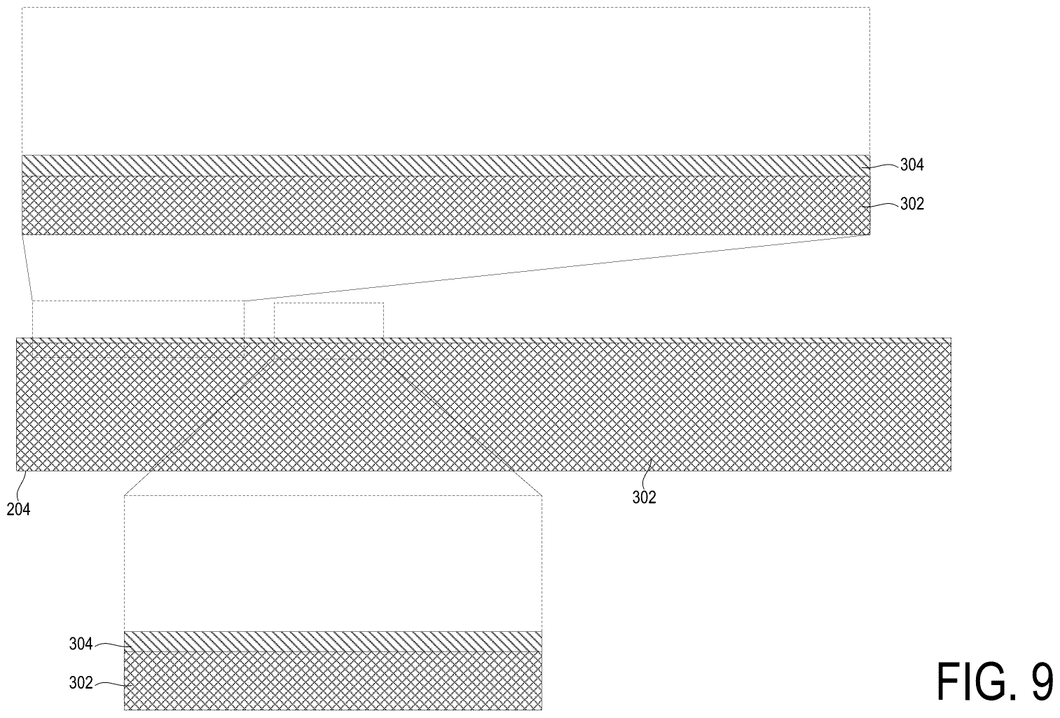

The method 700 begins in block 702 with a bare substrate, as shown in FIG. 8. In block 702, a dielectric layer 304 is deposited on the substrate 302, as shown in FIG. 9. It should be appreciated that, in the illustrative embodiment, the substrate 302 is flipped over before being mated with the EIC 202. As such, the substrate 302 is oriented in an opposite direction in FIGS. 8-16 as compared to, e.g., FIGS. 3 and 4.

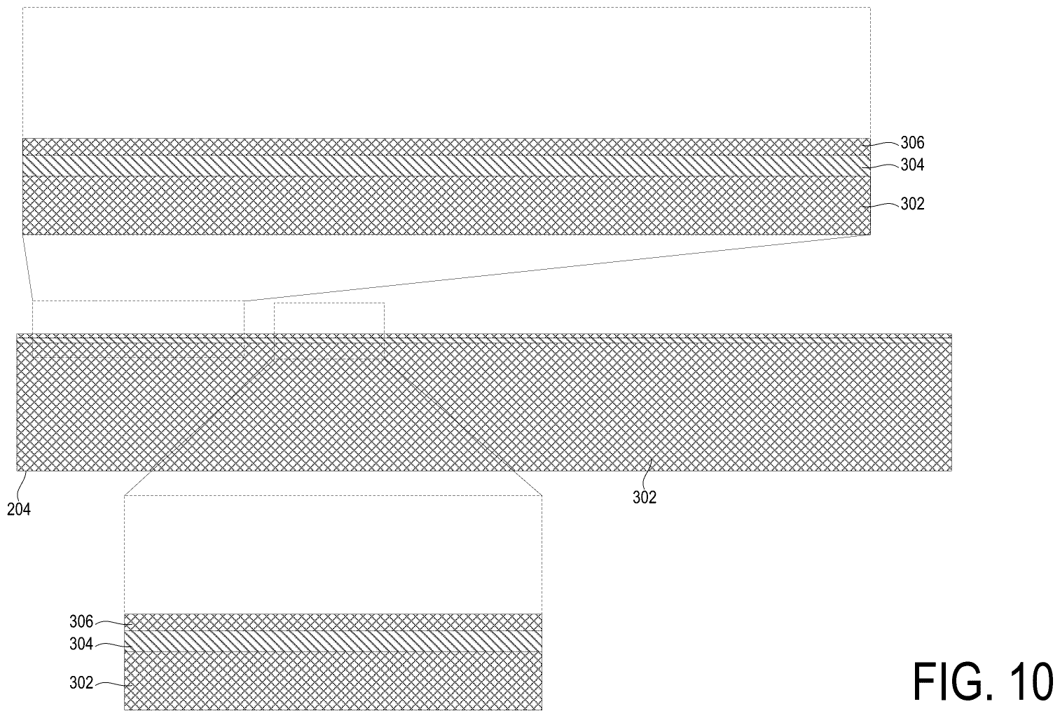

In block 704, a waveguide layer 306 is deposited on the dielectric layer 304, as shown in FIG. 10. The waveguide layer 306 may be grown directly on the dielectric layer 304 or the waveguide layer 306 may be deposited on the dielectric layer 304 using, e.g., layer transfer.

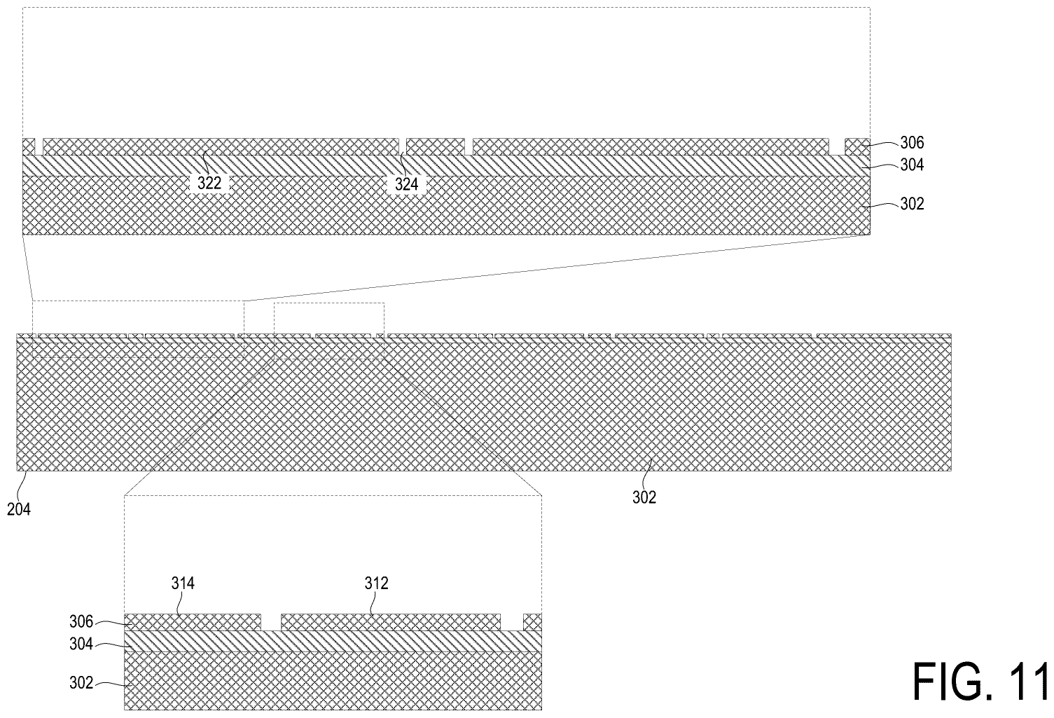

In block 706, the waveguide layer 306 may be patterned, removing some of the waveguide layer 306 and forming components such as waveguides 312 and isolated sections 314, 322, as shown in FIG. 11. In some embodiments, additional structures may be formed, such as microring resonators, couplers, splitters, filters, etc. In some embodiments, some or all of the structure of the waveguide layer 306 may be formed using additive manufacturing instead of subtractive manufacturing. In block 708, active devices are created on the waveguide layer 306, such as by doping the waveguide layer 306.

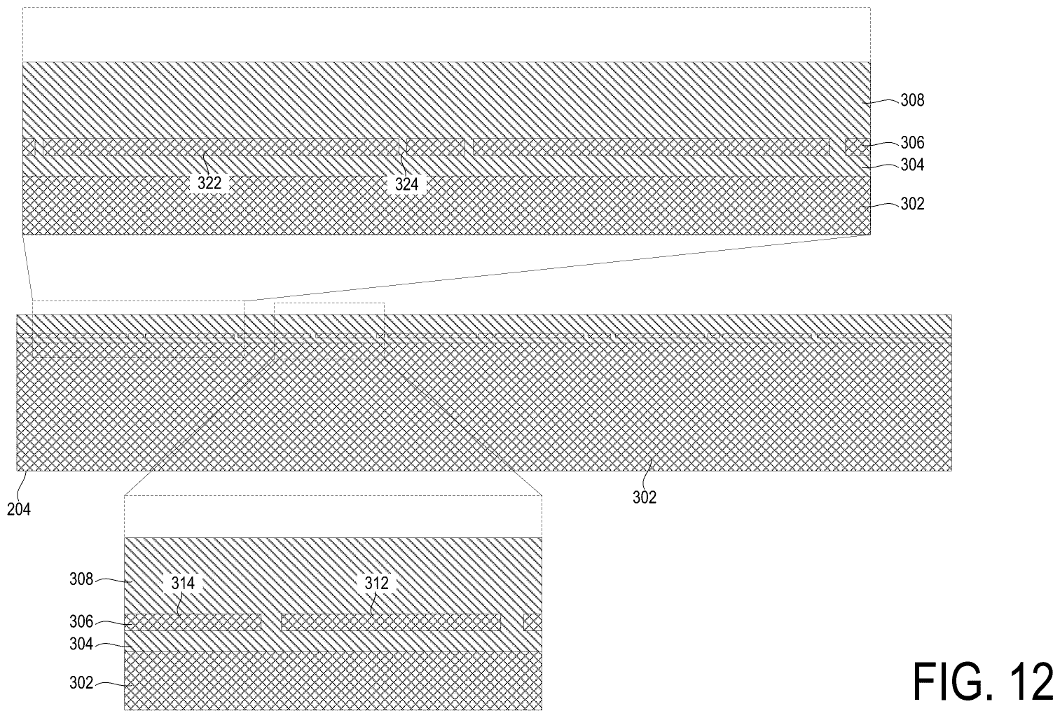

In block 710, a dielectric layer 308 is formed on the waveguide layer 306, as shown in FIG. 12. The dielectric material 324 filling in for the removed portions of the waveguide layer 306 may be deposited as part of depositing the dielectric layer, or the dielectric material 324 may be deposited at a separate step.

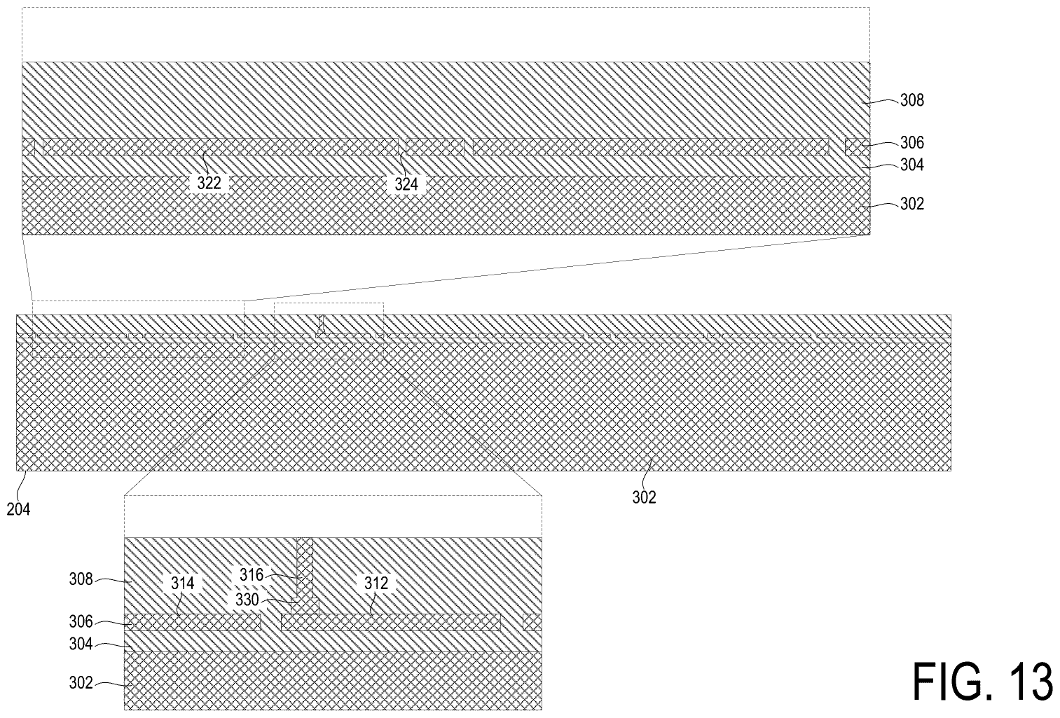

In block 712, plugs 316 are formed to active devices, such as waveguides 312, as shown in FIG. 13. In an illustrative embodiment, the plugs 316 are formed by creating a hole extending from the top of the dielectric layer 308 to the waveguide layer 306, and the hole is then filled in with, e.g., tungsten. The tungsten may be deposited on the outside of the holes and grow inwards, meeting near the middle. In some embodiments, a base 330 may be formed before the dielectric layer 308 is deposited, and the hole made in the dielectric layer 308 may extend to the base 330 before being filled in.

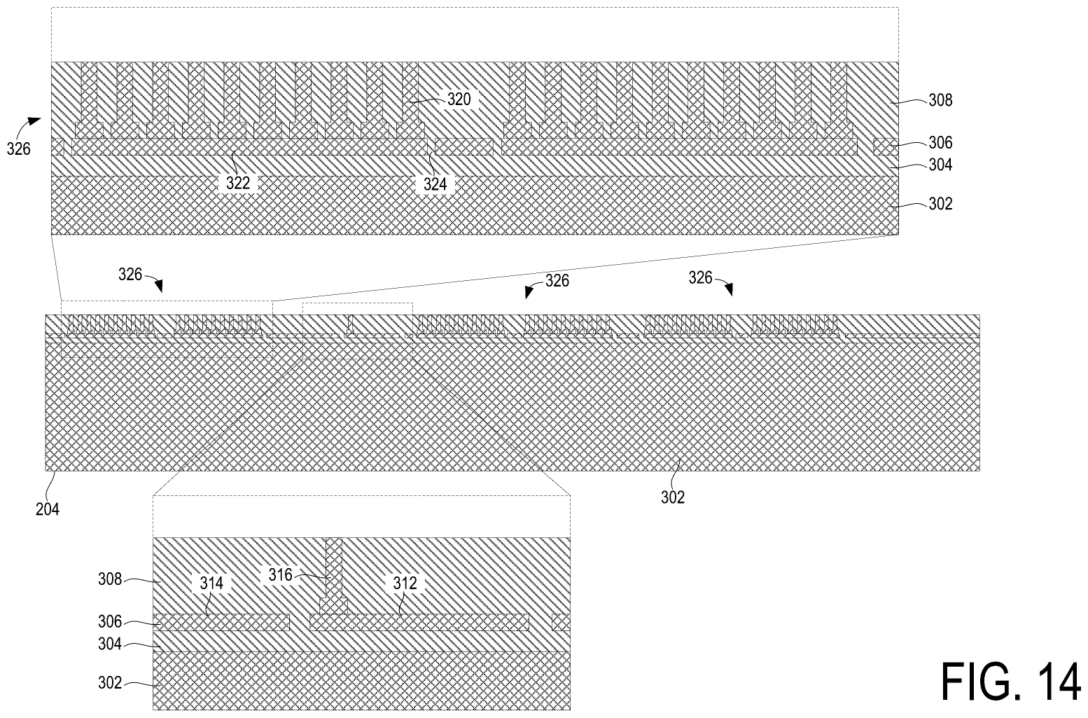

In block 714, thermals plugs 320 are formed in a similar manner to the plugs 316, as shown in FIG. 14. In some embodiments, thermal plugs 320 are formed that extend to the waveguide layer 306 in block 716. Additionally or alternatively, in some embodiments, thermal plugs 320 are formed that extend to through the waveguide layer 306 and the dielectric layer 304 to the substrate 302. One example of such plugs 320 is shown in FIG. 4. In some embodiments, the plugs 320 may be formed as part of the same step as forming the plugs 316.

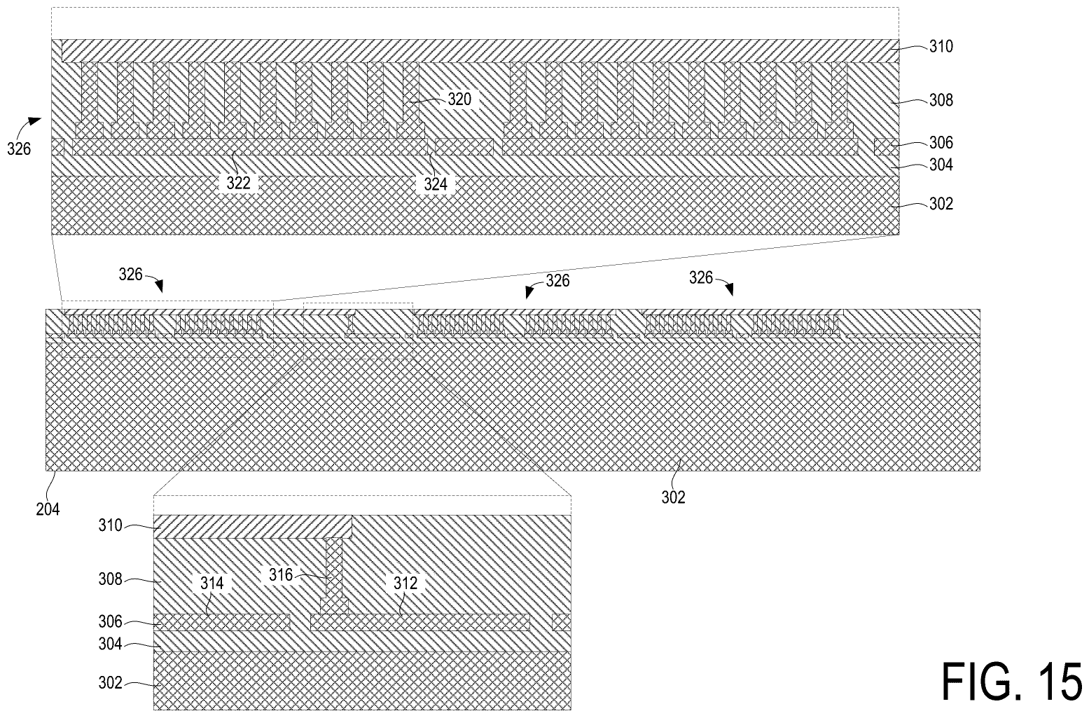

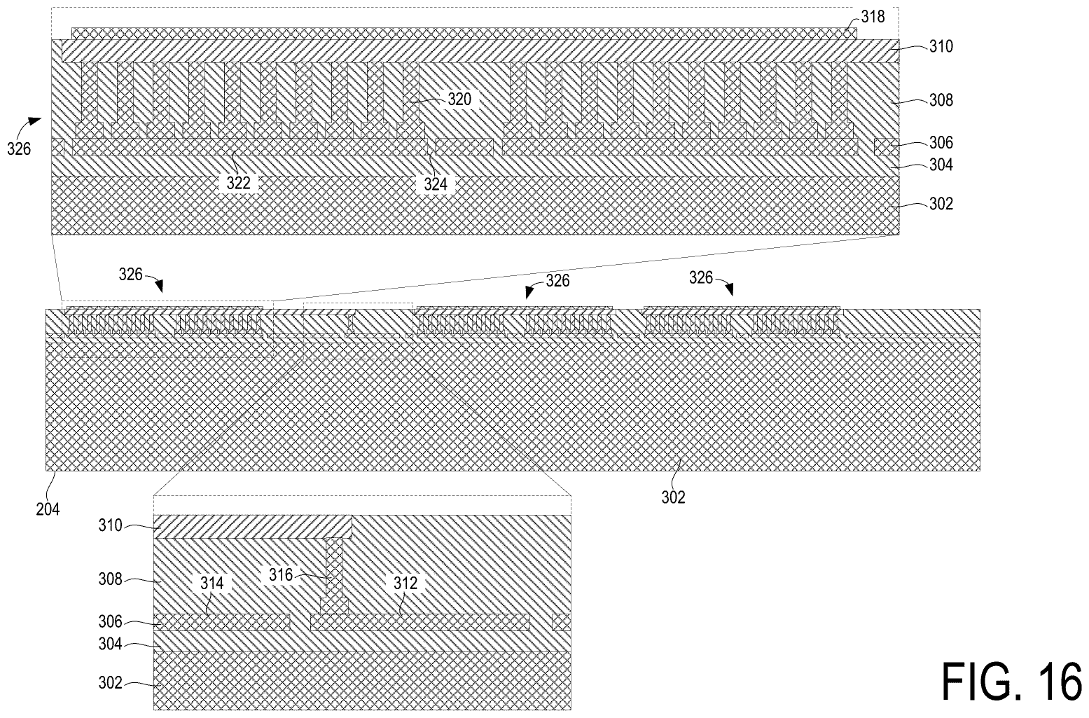

In block 720, a redistribution layer is formed on the dielectric layer 308, including traces 310, as shown in FIG. 15. The redistribution layer forms connections between various components, such as connections between two plugs 316 connected to active devices, connections between a contact 328 and a plug 316, etc. In block 722, contact pads 328 including a top pad layer 318 are formed, including over the groups 326 of thermal plugs 320, as shown in FIG. 16.

In block 724, the PIC die 204 is flipped over and mounted on the EIC die 202. The contact pads 328 of the PIC die 204 may aligned with solder balls 212 on the EIC die 202, and the EIC die 202 and PIC die 204 may be heated up until the solder 212 melts, joining the EIC die 202 and the PIC die 204.

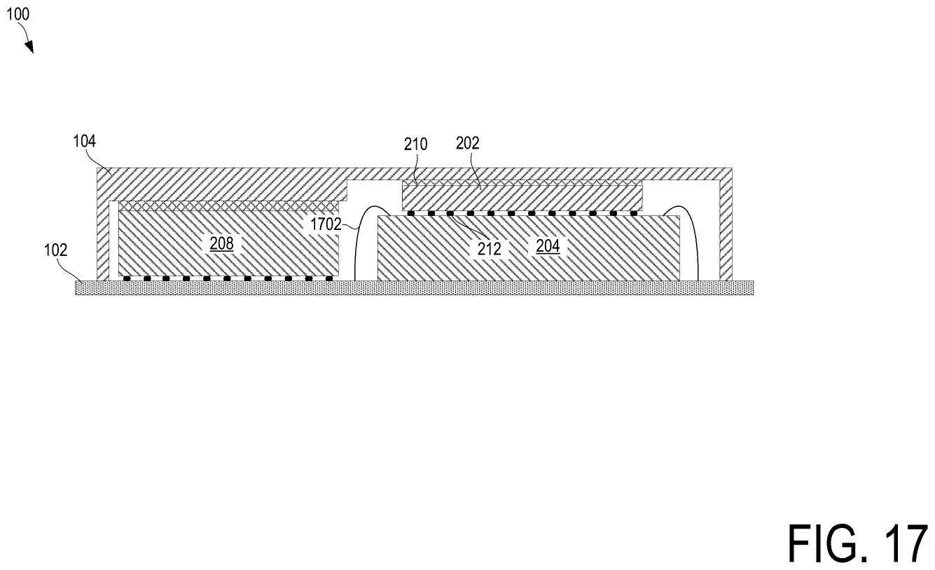

It should be appreciated that additional embodiments are envisioned beyond those described above. For example, referring now to FIG. 17, in one embodiment, an integrated circuit component 100 includes a PIC die 204 mounted on the circuit board 102. The PIC die 204 shown in FIG. 17 may be “face up,” with the active components, waveguides, etc., near the surface of the PIC die 204 closer to the heat sink 104. In addition to or in place of solder bumps, one or more wire bonds 1702 may connect the PIC die 204 to the circuit board 102. The wire bonds 1702 may carry power signals and/or data signals to and from the PIC die 204. In some cases, thermal plugs 320 may extend through the dielectric layer 308 towards a contact pad for a wire bond 1702 in a similar manner as the thermal plugs 320 may extend towards a contact pad 328 for a solder bump. The wire bond 1702 may carry away some heat from the PIC die 204. In some embodiments, an EIC die 202 may be mounted on the PIC die 204, such as by using one or more soler bumps 212, as shown in FIG. 17. In other embodiments, a top surface of the PIC die 204 may contact the integrated heat spreader 104, with a TIM 210 in between.

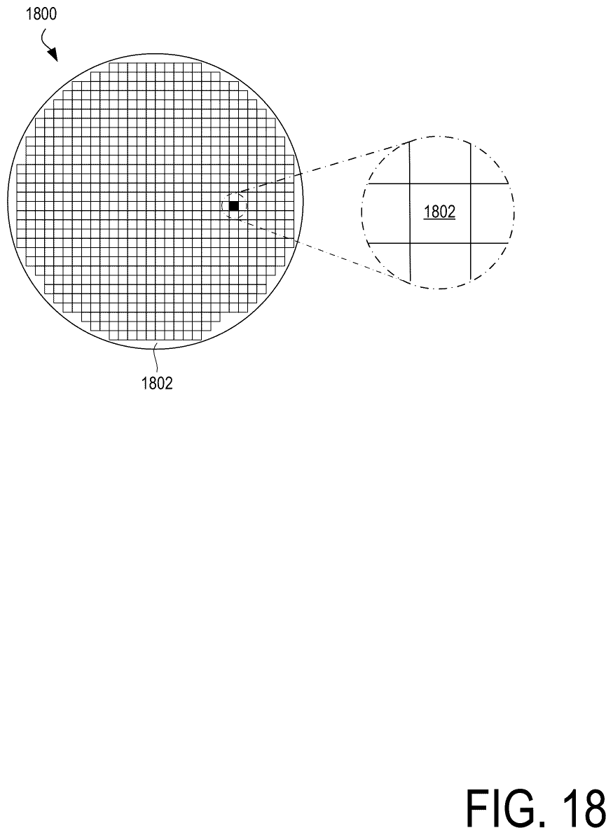

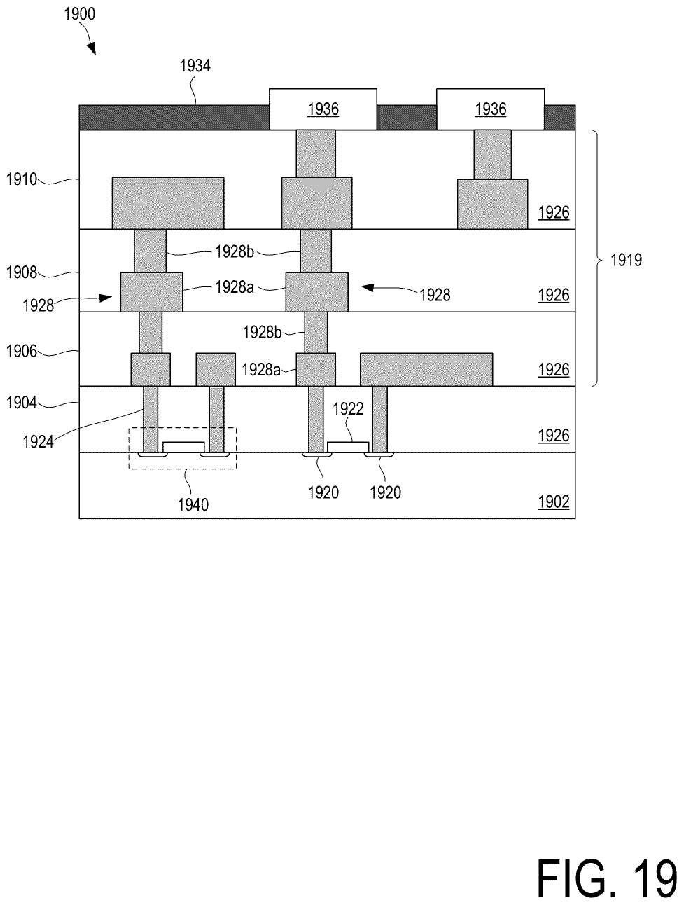

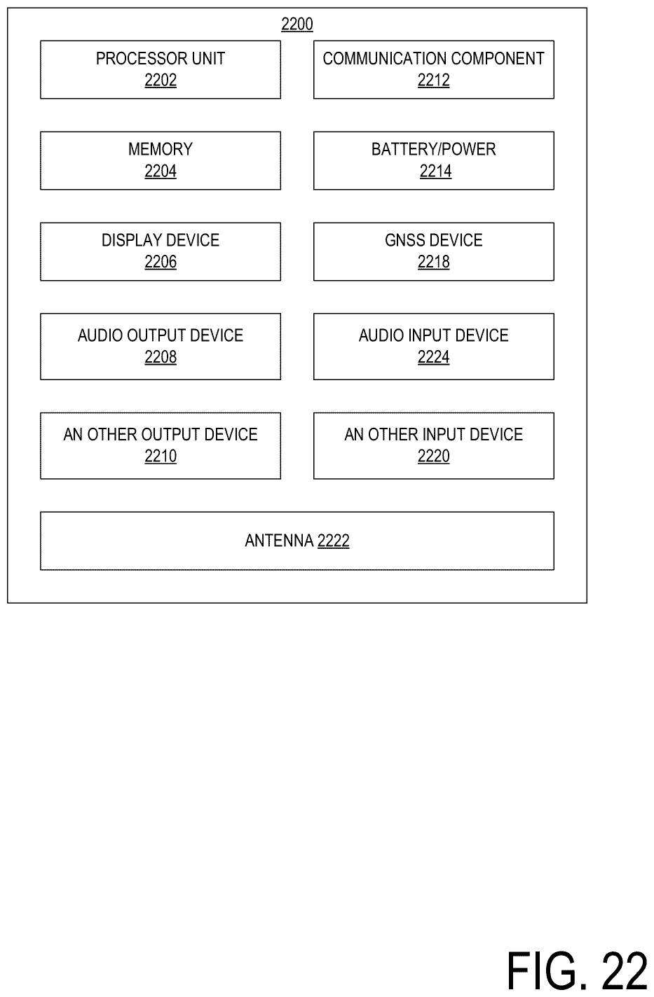

FIG. 18 is a top view of a wafer 1800 and dies 1802 that may be included in any of the integrated circuit components 100 disclosed herein (e.g., as any suitable ones of the dies 202, 204, 206, 208). The wafer 1800 may be composed of semiconductor material and may include one or more dies 1802 having integrated circuit structures formed on a surface of the wafer 1800. The individual dies 1802 may be a repeating unit of an integrated circuit product that includes any suitable integrated circuit. After the fabrication of the semiconductor product is complete, the wafer 1800 may undergo a singulation process in which the dies 1802 are separated from one another to provide discrete “chips” of the integrated circuit product. The die 1802 may be any of the dies 202, 204, 206, 208 disclosed herein. The die 1802 may include one or more transistors (e.g., some of the transistors 1940 of FIG. 19, discussed below), supporting circuitry to route electrical signals to the transistors, passive components (e.g., signal traces, resistors, capacitors, or inductors), and/or any other integrated circuit components. In some embodiments, the wafer 1800 or the die 1802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1802. For example, a memory array formed by multiple memory devices may be formed on a same die 1802 as a processor unit (e.g., the processor unit 2202 of FIG. 22) or other logic that is configured to store information in the memory devices or execute instructions stored in the memory array. Various ones of the integrated circuit components 100 disclosed herein may be manufactured using a die-to-wafer assembly technique in which some dies 202, 204, 206, 208 are attached to a wafer 1800 that include others of the dies 202, 204, 206, 208, and the wafer 1800 is subsequently singulated.

FIG. 19 is a cross-sectional side view of an integrated circuit device 1900 that may be included in any of the integrated circuit components 100 disclosed herein (e.g., in any of the dies 202, 204, 206, 208). One or more of the integrated circuit devices 1900 may be included in one or more dies 1802 (FIG. 18). The integrated circuit device 1900 may be formed on a die substrate 1902 (e.g., the wafer 1800 of FIG. 18) and may be included in a die (e.g., the die 1802 of FIG. 18). The die substrate 1902 may be a semiconductor substrate composed of semiconductor material systems including, for example, n-type or p-type materials systems (or a combination of both). The die substrate 1902 may include, for example, a crystalline substrate formed using a bulk silicon or a silicon-on-insulator (SOI) substructure. In some embodiments, the die substrate 1902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1902. Although a few examples of materials from which the die substrate 1902 may be formed are described here, any material that may serve as a foundation for an integrated circuit device 1900 may be used. The die substrate 1902 may be part of a singulated die (e.g., the dies 1802 of FIG. 18) or a wafer (e.g., the wafer 1800 of FIG. 18).

The integrated circuit device 1900 may include one or more device layers 1904 disposed on the die substrate 1902. The device layer 1904 may include features of one or more transistors 1940 (e.g., metal oxide semiconductor field-effect transistors (MOSFETs)) formed on the die substrate 1902. The transistors 1940 may include, for example, one or more source and/or drain (S/D) regions 1920, a gate 1922 to control current flow between the S/D regions 1920, and one or more S/D contacts 1924 to route electrical signals to/from the S/D regions 1920. The transistors 1940 may include additional features not depicted for the sake of clarity, such as device isolation regions, gate contacts, and the like. The transistors 1940 are not limited to the type and configuration depicted in FIG. 19 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

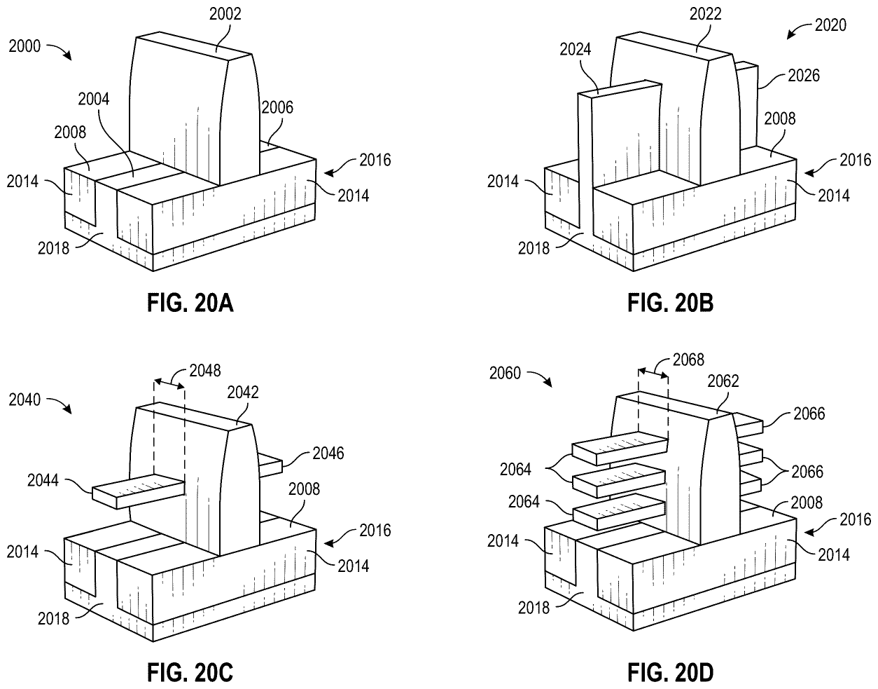

FIGS. 20A-20D are simplified perspective views of example planar, FinFET, gate-all-around, and stacked gate-all-around transistors. The transistors illustrated in FIGS. 20A-20D are formed on a substrate 2016 having a surface 2008. Isolation regions 2014 separate the source and drain regions of the transistors from other transistors and from a bulk region 2018 of the substrate 2016.

FIG. 20A is a perspective view of an example planar transistor 2000 comprising a gate 2002 that controls current flow between a source region 2004 and a drain region 2006. The transistor 2000 is planar in that the source region 2004 and the drain region 2006 are planar with respect to the substrate surface 2008.

FIG. 20B is a perspective view of an example FinFET transistor 2020 comprising a gate 2022 that controls current flow between a source region 2024 and a drain region 2026. The transistor 2020 is non-planar in that the source region 2024 and the drain region 2026 comprise “fins” that extend upwards from the substrate surface 2028. As the gate 2022 encompasses three sides of the semiconductor fin that extends from the source region 2024 to the drain region 2026, the transistor 2020 can be considered a tri-gate transistor. FIG. 20B illustrates one S/D fin extending through the gate 2022, but multiple S/D fins can extend through the gate of a FinFET transistor.

FIG. 20C is a perspective view of a gate-all-around (GAA) transistor 2040 comprising a gate 2042 that controls current flow between a source region 2044 and a drain region 2046. The transistor 2040 is non-planar in that the source region 2044 and the drain region 2046 are elevated from the substrate surface 2028.

FIG. 20D is a perspective view of a GAA transistor 2060 comprising a gate 2062 that controls current flow between multiple elevated source regions 2064 and multiple elevated drain regions 2066. The transistor 2060 is a stacked GAA transistor as the gate controls the flow of current between multiple elevated S/D regions stacked on top of each other. The transistors 2040 and 2060 are considered gate-all-around transistors as the gates encompass all sides of the semiconductor portions that extends from the source regions to the drain regions. The transistors 2040 and 2060 can alternatively be referred to as nanowire, nanosheet, or nanoribbon transistors depending on the width (e.g., widths 2048 and 2068 of transistors 2040 and 2060, respectively) of the semiconductor portions extending through the gate.

Returning to FIG. 19, a transistor 1940 may include a gate 1922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1940 along the source-channel-drain direction, the gate electrode may consist of a U-shaped structure that includes a bottom portion substantially parallel to the surface of the die substrate 1902 and two sidewall portions that are substantially perpendicular to the top surface of the die substrate 1902. In other embodiments, at least one of the metal layers that form the gate electrode may simply be a planar layer that is substantially parallel to the top surface of the die substrate 1902 and does not include sidewall portions substantially perpendicular to the top surface of the die substrate 1902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1920 may be formed within the die substrate 1902 adjacent to the gate 1922 of individual transistors 1940. The S/D regions 1920 may be formed using an implantation/diffusion process or an etching/deposition process, for example. In the former process, dopants such as boron, aluminum, antimony, phosphorous, or arsenic may be ion-implanted into the die substrate 1902 to form the S/D regions 1920. An annealing process that activates the dopants and causes them to diffuse farther into the die substrate 1902 may follow the ion-implantation process. In the latter process, the die substrate 1902 may first be etched to form recesses at the locations of the S/D regions 1920. An epitaxial deposition process may then be carried out to fill the recesses with material that is used to fabricate the S/D regions 1920. In some implementations, the S/D regions 1920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1920 may be formed using one or more alternate semiconductor materials such as germanium or a group III-V material or alloy. In further embodiments, one or more layers of metal and/or metal alloys may be used to form the S/D regions 1920.

Electrical signals, such as power and/or input/output (I/O) signals, may be routed to and/or from the devices (e.g., transistors 1940) of the device layer 1904 through one or more interconnect layers disposed on the device layer 1904 (illustrated in FIG. 19 as interconnect layers 1906-1910). For example, electrically conductive features of the device layer 1904 (e.g., the gate 1922 and the S/D contacts 1924) may be electrically coupled with the interconnect structures 1928 of the interconnect layers 1906-1910. The one or more interconnect layers 1906-1910 may form a metallization stack (also referred to as an “ILD stack”) 1919 of the integrated circuit device 1900.

The interconnect structures 1928 may be arranged within the interconnect layers 1906-1910 to route electrical signals according to a wide variety of designs; in particular, the arrangement is not limited to the particular configuration of interconnect structures 1928 depicted in FIG. 19. Although a particular number of interconnect layers 1906-1910 is depicted in FIG. 19, embodiments of the present disclosure include integrated circuit devices having more or fewer interconnect layers than depicted.

In some embodiments, the interconnect structures 1928 may include lines 1928a and/or vias 1928b filled with an electrically conductive material such as a metal. The lines 1928a may be arranged to route electrical signals in a direction of a plane that is substantially parallel with a surface of the die substrate 1902 upon which the device layer 1904 is formed. For example, the lines 1928a may route electrical signals in a direction in and out of the page and/or in a direction across the page. The vias 1928b may be arranged to route electrical signals in a direction of a plane that is substantially perpendicular to the surface of the die substrate 1902 upon which the device layer 1904 is formed. In some embodiments, the vias 1928b may electrically couple lines 1928a of different interconnect layers 1906-1910 together.

The interconnect layers 1906-1910 may include a dielectric material 1926 disposed between the interconnect structures 1928, as shown in FIG. 19. In some embodiments, dielectric material 1926 disposed between the interconnect structures 1928 in different ones of the interconnect layers 1906-1910 may have different compositions; in other embodiments, the composition of the dielectric material 1926 between different interconnect layers 1906-1910 may be the same. The device layer 1904 may include a dielectric material 1926 disposed between the transistors 1940 and a bottom layer of the metallization stack as well. The dielectric material 1926 included in the device layer 1904 may have a different composition than the dielectric material 1926 included in the interconnect layers 1906-1910; in other embodiments, the composition of the dielectric material 1926 in the device layer 1904 may be the same as a dielectric material 1926 included in any one of the interconnect layers 1906-1910.

A first interconnect layer 1906 (referred to as Metal 1 or “M1”) may be formed directly on the device layer 1904. In some embodiments, the first interconnect layer 1906 may include lines 1928a and/or vias 1928b, as shown. The lines 1928a of the first interconnect layer 1906 may be coupled with contacts (e.g., the S/D contacts 1924) of the device layer 1904. The vias 1928b of the first interconnect layer 1906 may be coupled with the lines 1928a of a second interconnect layer 1908.

The second interconnect layer 1908 (referred to as Metal 2 or “M2”) may be formed directly on the first interconnect layer 1906. In some embodiments, the second interconnect layer 1908 may include via 1928b to couple the lines 1928 of the second interconnect layer 1908 with the lines 1928a of a third interconnect layer 1910. Although the lines 1928a and the vias 1928b are structurally delineated with a line within individual interconnect layers for the sake of clarity, the lines 1928a and the vias 1928b may be structurally and/or materially contiguous (e.g., simultaneously filled during a dual-damascene process) in some embodiments.

The third interconnect layer 1910 (referred to as Metal 3 or “M3”) (and additional interconnect layers, as desired) may be formed in succession on the second interconnect layer 1908 according to similar techniques and configurations described in connection with the second interconnect layer 1908 or the first interconnect layer 1906. In some embodiments, the interconnect layers that are “higher up” in the metallization stack 1919 in the integrated circuit device 1900 (i.e., farther away from the device layer 1904) may be thicker that the interconnect layers that are lower in the metallization stack 1919, with lines 1928a and vias 1928b in the higher interconnect layers being thicker than those in the lower interconnect layers.

The integrated circuit device 1900 may include a solder resist material 1934 (e.g., polyimide or similar material) and one or more conductive contacts 1936 formed on the interconnect layers 1906-1910. In FIG. 19, the conductive contacts 1936 are illustrated as taking the form of bond pads. The conductive contacts 1936 may be electrically coupled with the interconnect structures 1928 and configured to route the electrical signals of the transistor(s) 1940 to external devices. For example, solder bonds may be formed on the one or more conductive contacts 1936 to mechanically and/or electrically couple an integrated circuit die including the integrated circuit device 1900 with another component (e.g., a printed circuit board). The integrated circuit device 1900 may include additional or alternate structures to route the electrical signals from the interconnect layers 1906-1910; for example, the conductive contacts 1936 may include other analogous features (e.g., posts) that route the electrical signals to external components. The conductive contacts 1936 may serve as the conductive contacts 328, as appropriate.

In some embodiments in which the integrated circuit device 1900 is a double-sided die, the integrated circuit device 1900 may include another metallization stack (not shown) on the opposite side of the device layer(s) 1904. This metallization stack may include multiple interconnect layers as discussed above with reference to the interconnect layers 1906-1910, to provide conductive pathways (e.g., including conductive lines and vias) between the device layer(s) 1904 and additional conductive contacts (not shown) on the opposite side of the integrated circuit device 1900 from the conductive contacts 1936. These additional conductive contacts may serve as the conductive contacts 328, as appropriate.

In other embodiments in which the integrated circuit device 1900 is a double-sided die, the integrated circuit device 1900 may include one or more through silicon vias (TSVs) through the die substrate 1902; these TSVs may make contact with the device layer(s) 1904, and may provide conductive pathways between the device layer(s) 1904 and additional conductive contacts (not shown) on the opposite side of the integrated circuit device 1900 from the conductive contacts 1936. These additional conductive contacts may serve as the conductive contacts 328, as appropriate. In some embodiments, TSVs extending through the substrate can be used for routing power and ground signals from conductive contacts on the opposite side of the integrated circuit device 1900 from the conductive contacts 1936 to the transistors 1940 and any other components integrated into the die 1900, and the metallization stack 1919 can be used to route I/O signals from the conductive contacts 1936 to transistors 1940 and any other components integrated into the die 1900.

Multiple integrated circuit devices 1900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

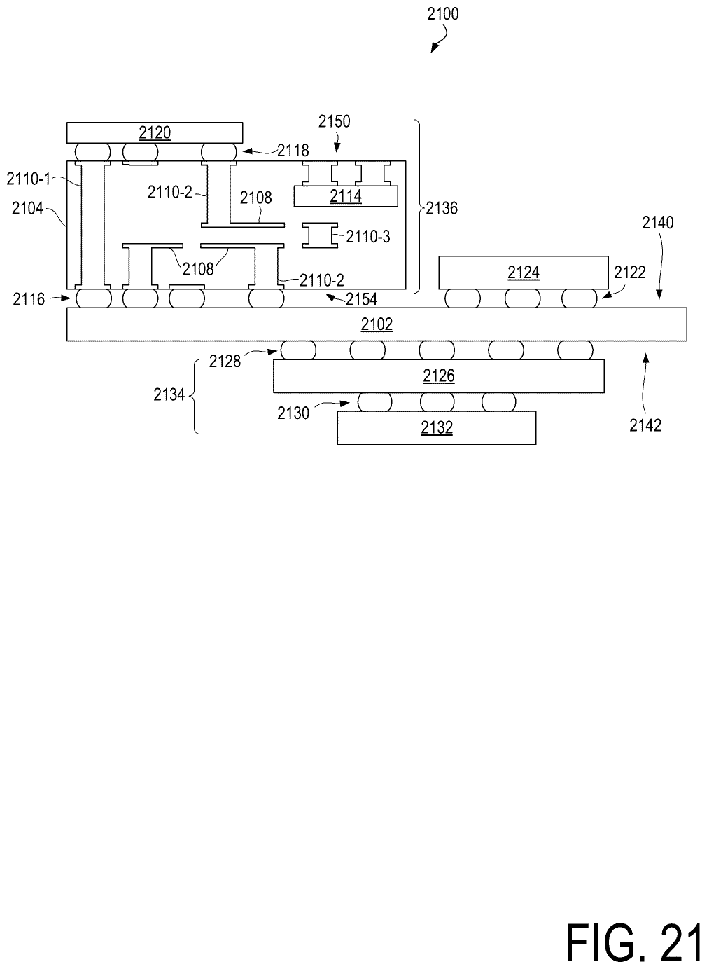

FIG. 21 is a cross-sectional side view of an integrated circuit device assembly 2100 that may include any of the integrated circuit components 100 disclosed herein. In some embodiments, the integrated circuit device assembly 2100 may be an integrated circuit component 100. The integrated circuit device assembly 2100 includes a number of components disposed on a circuit board 2102 (which may be a motherboard, system board, mainboard, etc.). The integrated circuit device assembly 2100 includes components disposed on a first face 2140 of the circuit board 2102 and an opposing second face 2142 of the circuit board 2102; generally, components may be disposed on one or both faces 2140 and 2142. Any of the integrated circuit components discussed below with reference to the integrated circuit device assembly 2100 may take the form of any suitable ones of the embodiments of the integrated circuit components 100 disclosed herein.

In some embodiments, the circuit board 2102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 2102. In other embodiments, the circuit board 2102 may be a non-PCB substrate. In some embodiments the circuit board 2102 may be, for example, the circuit board 102. The integrated circuit device assembly 2100 illustrated in FIG. 21 includes a package-on-interposer structure 2136 coupled to the first face 2140 of the circuit board 2102 by coupling components 2116. The coupling components 2116 may electrically and mechanically couple the package-on-interposer structure 2136 to the circuit board 2102, and may include solder balls (as shown in FIG. 21), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 2116 may serve as the coupling components illustrated or described for any of the substrate assembly or substrate assembly components described herein, as appropriate.

The package-on-interposer structure 2136 may include an integrated circuit component 2120 coupled to an interposer 2104 by coupling components 2118. The coupling components 2118 may take any suitable form for the application, such as the forms discussed above with reference to the coupling components 2116. Although a single integrated circuit component 2120 is shown in FIG. 21, multiple integrated circuit components may be coupled to the interposer 2104; indeed, additional interposers may be coupled to the interposer 2104. The interposer 2104 may provide an intervening substrate used to bridge the circuit board 2102 and the integrated circuit component 2120.

The integrated circuit component 2120 may be a packaged or unpacked integrated circuit product that includes one or more integrated circuit dies (e.g., the die 1802 of FIG. 18, the integrated circuit device 1900 of FIG. 19) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 2120, a single monolithic integrated circuit die comprises solder bumps attached to contacts on the die. The solder bumps allow the die to be directly attached to the interposer 2104. The integrated circuit component 2120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 2120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 2120 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 2120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 2104 may spread connections to a wider pitch or reroute a connection to a different connection. For example, the interposer 2104 may couple the integrated circuit component 2120 to a set of ball grid array (BGA) conductive contacts of the coupling components 2116 for coupling to the circuit board 2102. In the embodiment illustrated in FIG. 21, the integrated circuit component 2120 and the circuit board 2102 are attached to opposing sides of the interposer 2104; in other embodiments, the integrated circuit component 2120 and the circuit board 2102 may be attached to a same side of the interposer 2104. In some embodiments, three or more components may be interconnected by way of the interposer 2104.

In some embodiments, the interposer 2104 may be formed as a PCB, including multiple metal layers separated from one another by layers of dielectric material and interconnected by electrically conductive vias. In some embodiments, the interposer 2104 may be formed of an epoxy resin, a fiberglass-reinforced epoxy resin, an epoxy resin with inorganic fillers, a ceramic material, or a polymer material such as polyimide. In some embodiments, the interposer 2104 may be formed of alternate rigid or flexible materials that may include the same materials described above for use in a semiconductor substrate, such as silicon, germanium, and other group III-V and group IV materials. The interposer 2104 may include metal interconnects 2108 and vias 2110, including but not limited to through hole vias 2110-1 (that extend from a first face 2150 of the interposer 2104 to a second face 2154 of the interposer 2104), blind vias 2110-2 (that extend from the first or second faces 2150 or 2154 of the interposer 2104 to an internal metal layer), and buried vias 2110-3 (that connect internal metal layers).

In some embodiments, the interposer 2104 can comprise a silicon interposer. Through silicon vias (TSV) extending through the silicon interposer can connect connections on a first face of a silicon interposer to an opposing second face of the silicon interposer. In some embodiments, an interposer 2104 comprising a silicon interposer can further comprise one or more routing layers to route connections on a first face of the interposer 2104 to an opposing second face of the interposer 2104.

The interposer 2104 may further include embedded devices 2114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2104. The package-on-interposer structure 2136 may take the form of any of the package-on-interposer structures known in the art.

The integrated circuit device assembly 2100 may include an integrated circuit component 2124 coupled to the first face 2140 of the circuit board 2102 by coupling components 2122. The coupling components 2122 may take the form of any of the embodiments discussed above with reference to the coupling components 2116, and the integrated circuit component 2124 may take the form of any of the embodiments discussed above with reference to the integrated circuit component 2120.

The integrated circuit device assembly 2100 illustrated in FIG. 21 includes a package-on-package structure 2134 coupled to the second face 2142 of the circuit board 2102 by coupling components 2128. The package-on-package structure 2134 may include an integrated circuit component 2126 and an integrated circuit component 2132 coupled together by coupling components 2130 such that the integrated circuit component 2126 is disposed between the circuit board 2102 and the integrated circuit component 2132. The coupling components 2128 and 2130 may take the form of any of the embodiments of the coupling components 2116 discussed above, and the integrated circuit components 2126 and 2132 may take the form of any of the embodiments of the integrated circuit component 2120 discussed above. The package-on-package structure 2134 may be configured in accordance with any of the package-on-package structures known in the art.

FIG. 22 is a block diagram of an example electrical device 2200 that may include one or more of the integrated circuit components 100 disclosed herein. For example, any suitable ones of the components of the electrical device 2200 may include one or more of the integrated circuit device assemblies 2100, integrated circuit components 2120, integrated circuit devices 1900, or integrated circuit dies 1802 disclosed herein, and may be arranged in any of the integrated circuit components 100 disclosed herein. A number of components are illustrated in FIG. 22 as included in the electrical device 2200, but any one or more of these components may be omitted or duplicated, as suitable for the application. In some embodiments, some or all of the components included in the electrical device 2200 may be attached to one or more motherboards mainboards, or system boards. In some embodiments, one or more of these components are fabricated onto a single system-on-a-chip (SoC) die.

Additionally, in various embodiments, the electrical device 2200 may not include one or more of the components illustrated in FIG. 22, but the electrical device 2200 may include interface circuitry for coupling to the one or more components. For example, the electrical device 2200 may not include a display device 2206, but may include display device interface circuitry (e.g., a connector and driver circuitry) to which a display device 2206 may be coupled. In another set of examples, the electrical device 2200 may not include an audio input device 2224 or an audio output device 2208, but may include audio input or output device interface circuitry (e.g., connectors and supporting circuitry) to which an audio input device 2224 or audio output device 2208 may be coupled.

The electrical device 2200 may include one or more processor units 2202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 2202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 2200 may include a memory 2204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 2204 may include memory that is located on the same integrated circuit die as the processor unit 2202. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 2200 can comprise one or more processor units 2202 that are heterogeneous or asymmetric to another processor unit 2202 in the electrical device 2200. There can be a variety of differences between the processing units 2202 in a system in terms of a spectrum of metrics of merit including architectural, microarchitectural, thermal, power consumption characteristics, and the like. These differences can effectively manifest themselves as asymmetry and heterogeneity among the processor units 2202 in the electrical device 2200.

In some embodiments, the electrical device 2200 may include a communication component 2212 (e.g., one or more communication components). For example, the communication component 2212 can manage wireless communications for the transfer of data to and from the electrical device 2200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 2212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 2212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 2212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 2212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 2212 may operate in accordance with other wireless protocols in other embodiments. The electrical device 2200 may include an antenna 2222 to facilitate wireless communications and/or to receive other wireless communications (such as AM or FM radio transmissions).

In some embodiments, the communication component 2212 may manage wired communications, such as electrical, optical, or any other suitable communication protocols (e.g., IEEE 802.3 Ethernet standards). As noted above, the communication component 2212 may include multiple communication components. For instance, a first communication component 2212 may be dedicated to shorter-range wireless communications such as Wi-Fi or Bluetooth, and a second communication component 2212 may be dedicated to longer-range wireless communications such as global positioning system (GPS), EDGE, GPRS, CDMA, WiMAX, LTE, EV-DO, or others. In some embodiments, a first communication component 2212 may be dedicated to wireless communications, and a second communication component 2212 may be dedicated to wired communications.

The electrical device 2200 may include battery/power circuitry 2214. The battery/power circuitry 2214 may include one or more energy storage devices (e.g., batteries or capacitors) and/or circuitry for coupling components of the electrical device 2200 to an energy source separate from the electrical device 2200 (e.g., AC line power).

The electrical device 2200 may include a display device 2206 (or corresponding interface circuitry, as discussed above). The display device 2206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 2200 may include an audio output device 2208 (or corresponding interface circuitry, as discussed above). The audio output device 2208 may include any embedded or wired or wirelessly connected external device that generates an audible indicator, such as speakers, headsets, or earbuds.

The electrical device 2200 may include an audio input device 2224 (or corresponding interface circuitry, as discussed above). The audio input device 2224 may include any embedded or wired or wirelessly connected device that generates a signal representative of a sound, such as microphones, microphone arrays, or digital instruments (e.g., instruments having a musical instrument digital interface (MIDI) output). The electrical device 2200 may include a Global Navigation Satellite System (GNSS) device 2218 (or corresponding interface circuitry, as discussed above), such as a Global Positioning System (GPS) device. The GNSS device 2218 may be in communication with a satellite-based system and may determine a geolocation of the electrical device 2200 based on information received from one or more GNSS satellites, as known in the art.

The electrical device 2200 may include an other output device 2210 (or corresponding interface circuitry, as discussed above). Examples of the other output device 2210 may include an audio codec, a video codec, a printer, a wired or wireless transmitter for providing information to other devices, or an additional storage device.

The electrical device 2200 may include an other input device 2220 (or corresponding interface circuitry, as discussed above). Examples of the other input device 2220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 2200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 2200 may be any other electronic device that processes data. In some embodiments, the electrical device 2200 may comprise multiple discrete physical components. Given the range of devices that the electrical device 2200 can be manifested as in various embodiments, in some embodiments, the electrical device 2200 can be referred to as a computing device or a computing system.

### EXAMPLES

Illustrative examples of the technologies disclosed herein are provided below. An embodiment of the technologies may include any one or more, and any combination of, the examples described below.

Example 1 includes a photonic integrated circuit (PIC) die comprising a substrate layer; a first dielectric layer adjacent the substrate layer; a waveguide layer adjacent the first dielectric layer, wherein one or more waveguides are defined in the waveguide layer; a second dielectric layer adjacent the waveguide layer; and a plurality of contact pads adjacent the second dielectric layer, wherein, for individual contact pads of the plurality of contact pads, a plurality of plugs extend from the corresponding contact pad through the second dielectric layer.

Example 2 includes the subject matter of Example 1, and wherein, for individual contact pads of the plurality of contact pads, the plurality of plugs extending from the corresponding contact pad comprise a proximal end near the corresponding contact pad and a distal end opposite the proximal end, wherein, for individual contact pads of the plurality of contact pads, the distal ends of the plurality of plugs are not electrically coupled to any active component of the PIC die.

Example 3 includes the subject matter of any of Examples 1 and 2, and wherein, for individual contact pads of the plurality of contact pads, the plurality of plugs extend to an electrically isolated section of the waveguide layer, wherein the electrically isolated section comprises silicon.

Example 4 includes the subject matter of any of Examples 1-3, and wherein, for individual contact pads of the plurality of contact pads, the plurality of plugs extend to the substrate layer, wherein the substrate layer has a resistivity more than 10 Ohm-centimeter.

Example 5 includes the subject matter of any of Examples 1-4, and wherein, for individual contact pads of the plurality of contact pads, the plurality of plugs are arranged in a plurality of concentric rings.

Example 6 includes the subject matter of any of Examples 1-5, and wherein, for individual contact pads of the plurality of contact pads, the plurality of plugs have a thermal conductivity of at least 90 W/(m·K).

Example 7 includes the subject matter of any of Examples 1-6, and wherein, for individual contact pads of the plurality of contact pads, the plurality of plugs comprise tungsten.

Example 8 includes the subject matter of any of Examples 1-7, and wherein the substrate layer comprises silicon, wherein the first dielectric layer comprises silicon and oxygen, wherein the second dielectric layer comprises silicon and oxygen.

Example 9 includes an integrated circuit component comprising the PIC die of Example 1, further comprising an electronic integrated circuit (EIC) die mated with the PIC die; a plurality of solder balls positioned between the EIC die and the PIC die, wherein individual solder balls of the plurality of solder balls are adjacent individual contact pads of the plurality of contact pads of the PIC die; a circuit board mated to the EIC die; and an integrated heat spreader thermally coupled to the PIC die.

Example 10 includes an integrated circuit component comprising a photonic integrated circuit (PIC) die; an electronic integrated circuit (EIC) die mated with the PIC die; and a plurality of solder balls between the PIC die and the EIC die, wherein a plurality of contact pads are disposed on a surface of the PIC die, wherein individual contact pads of the plurality of contact pads are adjacent individual solder balls of the plurality of solder balls, wherein, for individual contact pads of the plurality of contact pads, a plurality of vias extend from the corresponding contact pad away from a surface of the PIC die, wherein, for individual contact pads of the plurality of contact pads, the plurality of vias extending from the corresponding contact pad comprise a proximal end near the corresponding contact pad and a distal end opposite the proximal end, wherein, for individual contact pads of the plurality of contact pads, the distal ends of the plurality of vias are not electrically coupled to any active component of the PIC die.

Example 11 includes the subject matter of Example 10, and wherein, for individual contact pads of the plurality of contact pads, the plurality of vias extend to an electrically isolated section of a waveguide layer, wherein the electrically isolated section comprises silicon.

Example 12 includes the subject matter of any of Examples 10 and 11, and wherein, for individual contact pads of the plurality of contact pads, the plurality of vias extend to an electrically isolated section of a waveguide layer of the PIC die, wherein the electrically isolated section comprises silicon.

Example 13 includes the subject matter of any of Examples 10-12, and wherein, for individual contact pads of the plurality of contact pads, the plurality of vias extend to a substrate layer of the PIC die, wherein the substrate layer has a resistivity more than 10 Ohm-centimeter.

Example 14 includes the subject matter of any of Examples 10-13, and wherein, for individual contact pads of the plurality of contact pads, the plurality of vias are arranged in a plurality of concentric rings.

Example 15 includes the subject matter of any of Examples 10-14, and wherein, for individual contact pads of the plurality of contact pads, the plurality of vias have a thermal conductivity of at least 90 W/(m·K).

Example 16 includes the subject matter of any of Examples 10-15, and wherein, for individual contact pads of the plurality of contact pads, the plurality of vias comprise tungsten.

Example 17 includes the subject matter of any of Examples 10-16, and wherein a substrate layer of the PIC die comprises silicon, wherein a dielectric layer of the PIC die comprises silicon and oxygen.

Example 18 includes the subject matter of any of Examples 10-17, and further including a circuit board mated to the EIC die; and an integrated heat spreader thermally coupled to the PIC die.

Example 19 includes a photonic integrated circuit (PIC) die comprising a substrate layer; a first dielectric layer adjacent the substrate layer; a waveguide layer adjacent the first dielectric layer, wherein one or more waveguides are defined in the waveguide layer; a second dielectric layer adjacent the waveguide layer; and a plurality of contact pads adjacent the second dielectric layer, means for conducting heat from the plurality of contact pads through the second dielectric layer.

Example 20 includes the subject matter of Example 19, and wherein the means for conducting heat comprise a proximal end near a corresponding contact pad and a distal end opposite the proximal end, wherein the distal ends of the means for conducting heat are not electrically coupled to any active component of the PIC die.

Example 21 includes the subject matter of any of Examples 19 and 20, and wherein the means for conducting heat extend to an electrically isolated section of the waveguide layer, wherein the electrically isolated section comprises silicon.

Example 22 includes the subject matter of any of Examples 19-21, and wherein the means for conducting heat extend to the substrate layer, wherein the substrate layer has a resistivity more than 10 Ohm-centimeter.

Example 23 includes the subject matter of any of Examples 19-22, and wherein the means for conducting heat comprises a plurality of concentric rings.

Example 24 includes the subject matter of any of Examples 19-23, and wherein the means for conducting heat has a thermal conductivity of at least 90 W/(m·K).

Example 25 includes the subject matter of any of Examples 19-24, and wherein the means for conducting heat comprise tungsten.

Example 26 includes the subject matter of any of Examples 19-25, and wherein the substrate layer comprises silicon, wherein the first dielectric layer comprises silicon and oxygen, wherein the second dielectric layer comprises silicon and oxygen.

Example 27 includes an integrated circuit component comprising the PIC die of Example 19, further comprising an electronic integrated circuit (EIC) die mated with the PIC die; a plurality of solder balls positioned between the EIC die and the PIC die, wherein individual solder balls of the plurality of solder balls are adjacent individual contact pads of the plurality of contact pads of the PIC die; a circuit board mated to the EIC die; and an integrated heat spreader thermally coupled to the PIC die.

1. A photonic integrated circuit (PIC) die comprising:
a substrate layer;
a first dielectric layer adjacent the substrate layer;
a waveguide layer adjacent the first dielectric layer, wherein one or more waveguides are defined in the waveguide layer;
a second dielectric layer adjacent the waveguide layer; and
a plurality of contact pads adjacent the second dielectric layer,
wherein, for individual contact pads of the plurality of contact pads, a plurality of plugs extend from the corresponding contact pad through the second dielectric layer.

2. The PIC die of claim 1, wherein, for individual contact pads of the plurality of contact pads, the plurality of plugs extending from the corresponding contact pad comprise a proximal end near the corresponding contact pad and a distal end opposite the proximal end, wherein, for individual contact pads of the plurality of contact pads, the distal ends of the plurality of plugs are not electrically coupled to any active component of the PIC die.

3. The PIC die of claim 1, wherein, for individual contact pads of the plurality of contact pads, the plurality of plugs extend to an electrically isolated section of the waveguide layer, wherein the electrically isolated section comprises silicon.

4. The PIC die of claim 1, wherein, for individual contact pads of the plurality of contact pads, the plurality of plugs extend to the substrate layer, wherein the substrate layer has a resistivity more than 10 Ohm-centimeter.

5. The PIC die of claim 1, wherein, for individual contact pads of the plurality of contact pads, the plurality of plugs are arranged in a plurality of concentric rings.

6. The PIC die of claim 1, wherein, for individual contact pads of the plurality of contact pads, the plurality of plugs have a thermal conductivity of at least 90 W/(m·K).

7. The PIC die of claim 1, wherein, for individual contact pads of the plurality of contact pads, the plurality of plugs comprise tungsten.

8. The PIC die of claim 1, wherein the substrate layer comprises silicon, wherein the first dielectric layer comprises silicon and oxygen, wherein the second dielectric layer comprises silicon and oxygen.

9. An integrated circuit component comprising the PIC die of claim 1, further comprising:
an electronic integrated circuit (EIC) die mated with the PIC die;
a plurality of solder balls positioned between the EIC die and the PIC die, wherein individual solder balls of the plurality of solder balls are adjacent individual contact pads of the plurality of contact pads of the PIC die;
a circuit board mated to the EIC die; and
an integrated heat spreader thermally coupled to the PIC die.

10. An integrated circuit component comprising:
a photonic integrated circuit (PIC) die;
an electronic integrated circuit (EIC) die mated with the PIC die; and
a plurality of solder balls between the PIC die and the EIC die,
wherein a plurality of contact pads are disposed on a surface of the PIC die, wherein individual contact pads of the plurality of contact pads are adjacent individual solder balls of the plurality of solder balls,
wherein, for individual contact pads of the plurality of contact pads, a plurality of vias extend from the corresponding contact pad away from a surface of the PIC die,
wherein, for individual contact pads of the plurality of contact pads, the plurality of vias extending from the corresponding contact pad comprise a proximal end near the corresponding contact pad and a distal end opposite the proximal end, wherein, for individual contact pads of the plurality of contact pads, the distal ends of the plurality of vias are not electrically coupled to any active component of the PIC die.

11. The integrated circuit component of claim 10, wherein, for individual contact pads of the plurality of contact pads, the plurality of vias extend to an electrically isolated section of a waveguide layer, wherein the electrically isolated section comprises silicon.

12. The integrated circuit component of claim 10, wherein, for individual contact pads of the plurality of contact pads, the plurality of vias extend to an electrically isolated section of a waveguide layer of the PIC die, wherein the electrically isolated section comprises silicon.

13. The integrated circuit component of claim 10, wherein, for individual contact pads of the plurality of contact pads, the plurality of vias extend to a substrate layer of the PIC die, wherein the substrate layer has a resistivity more than 10 Ohm-centimeter.

14. The integrated circuit component of claim 10, wherein, for individual contact pads of the plurality of contact pads, the plurality of vias are arranged in a plurality of concentric rings.

15. The integrated circuit component of claim 10, wherein, for individual contact pads of the plurality of contact pads, the plurality of vias have a thermal conductivity of at least 90 W/(m·K).

16. The integrated circuit component of claim 10, wherein, for individual contact pads of the plurality of contact pads, the plurality of vias comprise tungsten.

17. A photonic integrated circuit (PIC) die comprising:
a substrate layer;
a first dielectric layer adjacent the substrate layer;
a waveguide layer adjacent the first dielectric layer, wherein one or more waveguides are defined in the waveguide layer;
a second dielectric layer adjacent the waveguide layer; and
a plurality of contact pads adjacent the second dielectric layer,
means for conducting heat from the plurality of contact pads through the second dielectric layer.

18. The PIC die of claim 17, wherein the means for conducting heat comprise a proximal end near a corresponding contact pad and a distal end opposite the proximal end, wherein the distal ends of the means for conducting heat are not electrically coupled to any active component of the PIC die.

19. The PIC die of claim 17, wherein the means for conducting heat extend to the substrate layer, wherein the substrate layer has a resistivity more than 10 Ohm-centimeter.

20. The PIC die of claim 17, wherein the means for conducting heat comprises a plurality of concentric rings.
